(19) United States
(12) Patent Application Publication
(10) Pub. No.: US 2025/0309177 A1
(43) Pub. Date: Oct. 2, 2025

(54) SEMICONDUCTOR PACKAGES

(71) Applicant: Samsung Electronics Co., Ltd., Suwon-si (KR)

(72) Inventors: Keunyoung Lee, Suwon-si (KR); Kihong Jeong, Suwon-si (KR)

(21) Appl. No.: 19/045,974

(22) Filed: Feb. 5, 2025

(30) Foreign Application Priority Data
Mar. 28, 2024 (KR) 10-2024-0042242

(51) Int. Cl. H01L 23/00; H01L 23/31; H01L 23/538; H01L 25/07

(52) U.S. Cl. CPC H01L 24/48; H01L 23/5386; H01L 24/49; H01L 25/071; H01L 23/3107; H01L 2224/48108; H01L 2224/48145; H01L 2224/48228; H01L 2224/49112; H01L 2225/06506; H01L 2225/0651; H01L 2225/06562

(57) ABSTRACT

A semiconductor package includes a package substrate having first substrate pads spaced apart from each other in a first direction and second substrate pads electrically connected to the first substrate pads, a buffer chip disposed on the package substrate and having buffer chip pads, a first group of semiconductor chips disposed on the package substrate, a second group of semiconductor chips stacked on the first group of semiconductor chips, first bonding wires electrically connecting the buffer chip pads to the first substrate pads, and second bonding wires electrically connecting chip pads of the first group of semiconductor chips and chip pads of the second group of semiconductor chips to the second substrate pads. The buffer chip pads include first channel buffer pads and second channel buffer pads that are alternately arranged along a first side of the buffer chip.

### CROSS-REFERENCE TO RELATED APPLICATION

This application claims priority under 35 U.S.C. § 119 to Korean Patent Application No. 10-2024-0042242, filed on Mar. 28, 2024 in the Korean Intellectual Property Office (KIPO), the contents of which are herein incorporated by reference in their entirety.

### BACKGROUND OF THE INVENTION

### 1. Field and Background of the Invention

Example embodiments relate to semiconductors (e.g., semiconductor packages). More particularly, example embodiments relate to a semiconductor package including a plurality of chips (sequentially) stacked on a package substrate by adhesive films.

### 2. Description of the Related Art

A NAND flash memory device may be implemented as a multi-chip package (MCP) including a plurality of memory chips stacked on a package substrate to provide high storage capacity. The MCP may include a buffer chip for improving an input/output (I/O) speed. The buffer chip may implement and evenly distribute two internal I/O buses between the memory chips and an external controller to reduce a capacitive load on controller-to-NAND interfaces by half. However, since the buffer chip has signal pad areas that are arranged separately for each internal channel, there is a problem in that the package substrate requires additional wiring layers and routing space for signal routing between the buffer chip and the memory chips.

### SUMMARY OF THE INVENTION

Example embodiments provide a semiconductor package capable of providing an optimized routing design and having improved electrical characteristics.

According to example embodiments, a semiconductor package includes a package substrate having first substrate pads and second substrate pads on an upper surface of the package substrate, wherein the first substrate pads are spaced apart from each other in a first direction that is parallel with the upper surface of the package substrate, and the second substrate pads are electrically connected to the first substrate pads, respectively, by first substrate wirings that are in the package substrate; a first buffer chip on the upper surface of the package substrate, wherein the first buffer chip has a first side and a second side that extend in the first direction and that are opposite to each other in a second direction that is parallel with the upper surface of the package substrate, and the first buffer chip includes first buffer chip pads on an upper surface of the first buffer chip; a first group of semiconductor chips on the upper surface of the package substrate and including at least two first lower semiconductor chips, wherein the at least two first lower semiconductor chips include first lower chip pads on upper surfaces of the at least two first lower semiconductor chips; a second group of semiconductor chips on the first group of semiconductor chips and including at least two first upper semiconductor chips, wherein the at least two first upper semiconductor chips include first upper chip pads on upper surfaces of the at least two first upper semiconductor chips; first bonding wires electrically connecting the first buffer chip pads of the first buffer chip to the first substrate pads of the package substrate; and second bonding wires electrically connecting the first lower chip pads and the first upper chip pads to the second substrate pads of the package substrate, wherein the first direction and the second direction intersect each other, wherein the first buffer chip pads include first channel buffer pads and second channel buffer pads that are alternately arranged in the first direction along the first side of the first buffer chip, wherein the first channel buffer pads are electrically connected to the first lower chip pads by the first bonding wires and the second bonding wires, and wherein the second channel buffer pads are electrically connected to the first upper chip pads by the first bonding wires and the second bonding wires.

According to example embodiments, a semiconductor package includes a package substrate having external channel substrate pads, first substrate pads, and second substrate pads on an upper surface of the package substrate, wherein the first substrate pads and the second substrate pads are electrically connected to each other in one-to-one correspondence; a first buffer chip on the upper surface of the package substrate, wherein the first buffer chip has a first side and a second side that that are opposite to each other in a first direction, and the first buffer chip includes first buffer chip pads that are arranged in a second direction along the first side and external channel chip pads that are arranged in the second direction along the second side; a first group of semiconductor chips on the upper surface of the package substrate and including at least two first lower semiconductor chips, wherein the at least two first lower semiconductor chips include first lower chip pads on upper surfaces of the at least two first lower semiconductor chips; a second group of semiconductor chips on the first group of semiconductor chips and including at least two first upper semiconductor chips, wherein the at least two first upper semiconductor chips include first upper chip pads on upper surfaces of the at least two first upper semiconductor chips; first bonding wires electrically connecting the first buffer chip pads of the first buffer chip to the first substrate pads of the package substrate; second bonding wires electrically connecting the external channel chip pads of the first buffer chip to the external channel substrate pads of the package substrate; and third bonding wires electrically connecting the first lower chip pads and the first upper chip pads to the second substrate pads of the package substrate, wherein the first direction and the second direction are parallel with the upper surface of the package substrate, wherein the first direction and the second direction intersect each other, wherein the first buffer chip pads include first channel buffer pads and second channel buffer pads that are alternately arranged in the second direction along the first side of the first buffer chip, wherein the first substrate pads include first channel buffer-side pads and second channel buffer-side pads, wherein the first channel buffer-side pads are electrically connected to the first channel buffer pads in one-to-one correspondence, wherein the second channel buffer-side pads are electrically connected to the second channel buffer pads in one-to-one correspondence, wherein the second substrate pads include first channel memory-side pads and second channel memory-side pads, wherein the first channel memory-side pads are electrically connected to the first channel buffer-side pads in one-to-one correspondence, and wherein the second channel memory-side pads are electrically connected to the second channel buffer-side pads in one-to-one correspondence.

According to example embodiments, a semiconductor package includes a package substrate having first substrate pads and second substrate pads on an upper surface of the package substrate, wherein the first substrate pads and the second substrate pads are electrically connected to each other in one-to-one correspondence; a buffer chip on the upper surface of the package substrate, wherein the buffer chip has a first side and a second side that are opposite to each other in a first direction, and the buffer chip includes buffer chip pads arranged in a second direction along the first side; a first group of semiconductor chips including at least two lower semiconductor chips that are sequentially stacked on the upper surface of the package substrate; a second group of semiconductor chips including at least two upper semiconductor chips that are sequentially stacked on the first group of semiconductor chips; first bonding wires electrically connecting the buffer chip pads of the buffer chip to the first substrate pads of the package substrate; and second bonding wires electrically connecting lower chip pads of the first group of semiconductor chips and upper chip pads of the second group of semiconductor chips to the second substrate pads of the package substrate, wherein the buffer chip pads include first channel buffer pads and second channel buffer pads that are alternately arranged in the second direction along the first side, wherein the first direction and the second direction are parallel with the upper surface of the package substrate, wherein the first direction and the second direction intersect each other, wherein the first substrate pads include first channel buffer-side pads and second channel buffer-side pads, wherein the first channel buffer-side pads are electrically connected to the first channel buffer pads in one-to-one correspondence, wherein the second channel buffer-side pads are electrically connected to the second channel buffer pads in one-to-one correspondence, wherein the second substrate pads include first channel memory-side pads and second channel memory-side pads, wherein the first channel memory-side pads are electrically connected to the first channel buffer-side pads in one-to-one correspondence, wherein the second channel memory-side pads are electrically connected to the second channel buffer-side pads in one-to-one correspondence, wherein the first channel buffer pads, the first channel buffer-side pads, and the first channel memory-side pads constitute at least a portion of a first channel for transmitting data signals between the buffer chip and the first group of semiconductor chips, and wherein the second channel buffer pads, the second channel buffer-side pads, and the second channel memory-side pads constitute at least a portion of a second channel for transmitting data signals between the buffer chip and the first group of semiconductor chips.

According to example embodiments, a semiconductor package may include a package substrate, a buffer chip on an upper surface of the package substrate and having buffer chip pads, a first group of semiconductor chips arranged on the upper surface of the package substrate, a second group of semiconductor chips stacked on the first group of semiconductor chips, first bonding wires electrically connecting the buffer chip pads of the buffer chip to the package substrate, and second bonding wires electrically connecting chip pads of the first group of semiconductor chips and chip pads of the second group of semiconductor chips to the package substrate. The buffer chip pads may include first channel buffer pads and second channel buffer pads that alternately arranged in a first direction along a first side of the buffer chip.

The package substrate may include first channel buffer-side pads and first channel memory-side pads for electrically connecting the first channel buffer pads and the chip pads of the first group of semiconductor chips, and second channel buffer-side pads and second channel memory-side pads for electrically connecting the second channel buffer pads and the chip pads of the second group of semiconductor chips.

Since the first and second channel buffer pads are arranged alternately in the first direction, the first and second channel buffer-side pads and the first and second channel memory-side pads may also be arranged alternately. Accordingly, first internal wirings that electrically connect the first channel buffer-side pads and the first channel memory-side pads, and second internal wirings that electrically connect the second channel buffer-side pads and the second channel memory-side pads may be arranged alternately in the first direction, so that the first internal wirings and the second internal wirings may be arranged on the same circuit layer. Accordingly, the first internal wirings and the second internal wirings may be designed to extend not to cross each other on the same circuit layer. Thus, the buffer chip may alternately arrange data pads for different internal channels to provide a routing space for an optimized routing design.

### BRIEF DESCRIPTION OF THE DRAWINGS

Example embodiments will be more clearly understood from the following detailed description taken in conjunction with the accompanying drawings. FIGS. 1 to 18 represent non-limiting, example embodiments as described herein.

FIG. 1 is a block diagram illustrating a semiconductor package in accordance with example embodiments.

FIG. 2 is a cross-sectional view illustrating a semiconductor package in accordance with example embodiments.

FIG. 3 is a plan view of the semiconductor package of FIG. 2.

FIG. 4 is an enlarged plan view illustrating portion ‘A’ in FIG. 3.

FIG. 5 is a cross-sectional view taken along the line B-B′ in FIG. 4.

FIG. 6 is a cross-sectional view taken along the line C-C′ in FIG. 4.

FIG. 7 is a perspective view illustrating portion ‘A’ in FIG. 3.

FIG. 8 is a cross-sectional view illustrating a semiconductor package in accordance with example embodiments.

FIG. 9 is a block diagram illustrating a semiconductor package in accordance with example embodiments.

FIG. 10 is a cross-sectional view illustrating the semiconductor package in FIG. 9.

FIG. 11 is a plan view of the semiconductor package of FIG. 10.

FIG. 12 is a cross-sectional view illustrating a semiconductor package in accordance with example embodiments.

FIG. 13 is a cross-sectional view illustrating a semiconductor package with accordance with example embodiments.

FIG. 14 is a cross-sectional view illustrating a semiconductor package in accordance with example embodiments.

FIG. 15 is a cross-sectional view illustrating a semiconductor package in accordance with example embodiments.

FIG. 16 is a cross-sectional view illustrating a semiconductor package in accordance with example embodiments.

FIG. 17 is a plan view illustrating a portion of the semiconductor package in FIG. 16.

FIG. 18 is a cross-sectional view illustrating a semiconductor package in accordance with example embodiments.

### DETAILED DESCRIPTION OF THE INVENTION

Hereinafter, example embodiments will be explained in detail with reference to the accompanying drawings.

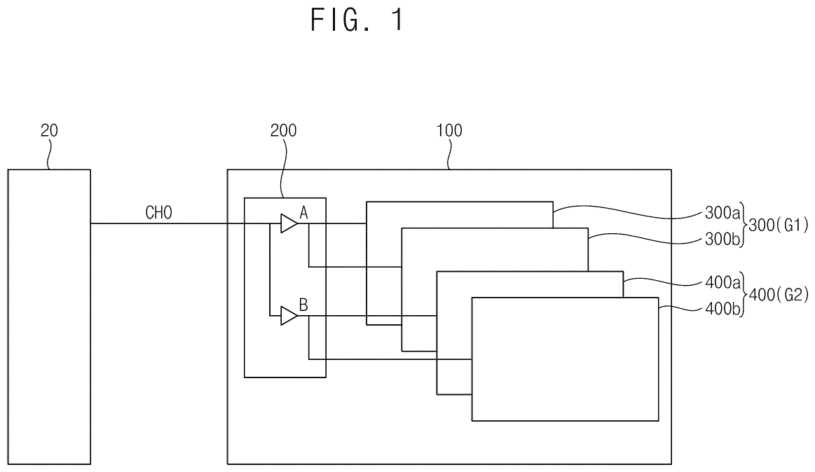

FIG. 1 is a block diagram illustrating a semiconductor package in accordance with example embodiments.

Referring to FIG. 1, a semiconductor package 100 may include a buffer chip 200, a first group of semiconductor chips G1, and a second group of semiconductor chips G2. The semiconductor package 100 may be (electrically) connected to a host 20 through an external channel CH0. The host 20 may include a controller that controls an operation of the semiconductor package 100. Therefore, the host 20 may be referred to as an external controller or a controller. Various signals, such as data signals and control signals, may be transmitted between the host 20 and the semiconductor package 100 through the external channel CH0. It will be understood that when an element or layer is referred to as being “on”, “responsive to”, “connected to”, or “coupled to” another element or layer, it may be directly on, responsive to, connected to, or coupled to the other element or layer, or one or more intervening elements or layers may be present. In contrast, when an element is referred to as being “directly on”, “directly responsive to”, “directly connected to”, or “directly coupled to” another element, there are no intervening elements present. In addition, “electrical connection” conceptually includes a physical connection and a physical disconnection.

In example embodiments, the buffer chip 200 may be (electrically) connected to the controller 20 by the external channel CH0. The buffer chip 200 may implement and (evenly) distribute first and second internal channels A and B as two internal I/O buses between the first and second groups of the semiconductor chips G1 and G2 and the external controller 20. For example, the buffer chip 200 may include a frequency boosting interface (FBI) chip. In some embodiments, the first group of the semiconductor chips G1 and the second group of the semiconductor chips G2 may be a first group of the memory chips and a second group of the memory chips, respectively and may be collectively or separately referred as (a plurality of) memory chips. The first group of the semiconductor chips G1 and the second group of the semiconductor chips G2 may be referred to as the first group of the semiconductor chips 300 and the second group of the semiconductor chips 400, respectively.

For example, the first group of semiconductor chips G1 and the buffer chip 200 may be (electrically) connected to each other by the first internal channel A, and electrical signals such as data signals, control signals, etc. may be transmitted between the first group of semiconductor chips G1 and the buffer chip 200 through the first internal channel A. The second group of semiconductor chips G2 and the buffer chip 200 may be (electrically) connected to each other by the second internal channel B, and electrical signals such as data signals, control signals, etc. may be transmitted between the second group of semiconductor chips G2 and the buffer chip 200 through the second internal channel B.

The buffer chip 200 may perform a function of selectively (and electrically) connecting the external channel CH0 to one of the first and second internal channels A and B according to a signal, for example, a chip selection signal received from the host 20 (e.g., the controller), and thus, it may enable an operation between one of the first and second groups of the semiconductor chips G1 and G2 (e.g., the first and second groups of the memory chips) and the host 20 (e.g., the controller). For example, during a write operation, a data signal may be output to one of the first and second internal channels A and B through the buffer chip 200, and thus, data may be stored in one of the first and second groups of the semiconductor chips G1 and G2 (e.g., the first and second groups of the memory chips). In addition, during a read operation, data read from one of the first and second groups of the semiconductor chips G1 and G2 (e.g., the first and second groups of the memory chips) may be output to one of the first and second internal channels A and B and then may be output to the external channel CH0 through the buffer chip 200.

The first group of semiconductor chips G1 may include at least two semiconductor chips 300a, 300b. The second group of semiconductor chips G2 may include at least two semiconductor chips 400a, 400b. The first group of semiconductor chips G1 and the second group of semiconductor chips G2 may include various types of memory chips. The memory chips may include, for example, volatile memory devices such as SRAM devices, DRAM devices, and the like, and nonvolatile memory devices such as flash memory devices, PRAM devices, MRAM devices, RRAM devices, and the like. In this embodiment, the case where each of the first group of semiconductor chips G1 and the second group of semiconductor chips G2 includes two semiconductor chips has been described, but is not limited thereto.

The controller of the host 20 may control the overall operation of the semiconductor package 100, such as a read operation, a write operation, etc. The controller may include a central processing unit CPU, a memory controller, an application specific integrated circuit ASIC, an application processor AP, etc.

As described above, the semiconductor package 100 may include the buffer chip 200 that (electrically) connects the external channel CH0 and (at least) one of a plurality of internal channels A and B (at least one of the first and second internal channels A and B), so that the semiconductor package 100 can have an improved input/output (I/O) speed and can process a large (a larger) amount of data compared to a conventional semiconductor package having one internal channel corresponding to one external channel. Further, in this embodiment, the buffer chip 200 may provide alternately arranged pads for different internal channels (e.g., the first and second internal channels A and B) to provide a routing space for an optimized routing design. Hereinafter, an optimized routing design for the internal channels of the semiconductor package will be described in detail.

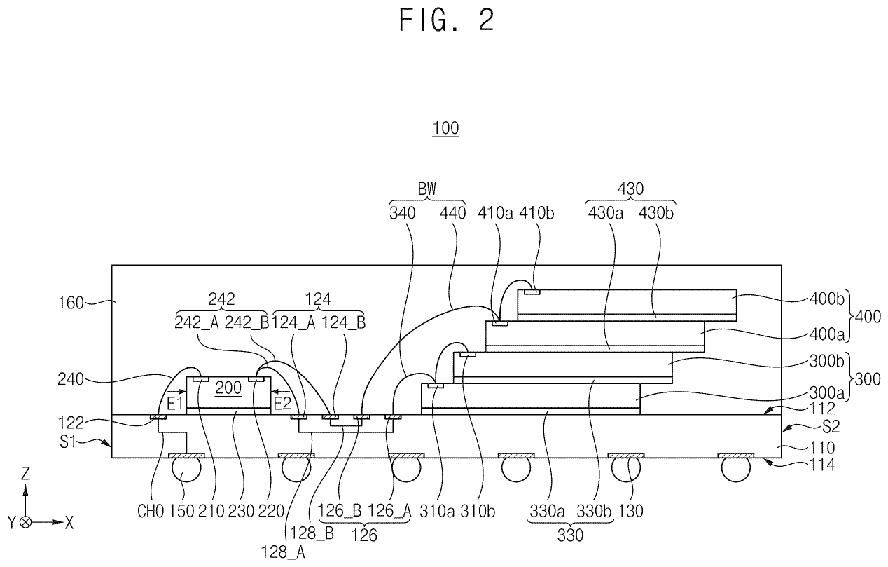

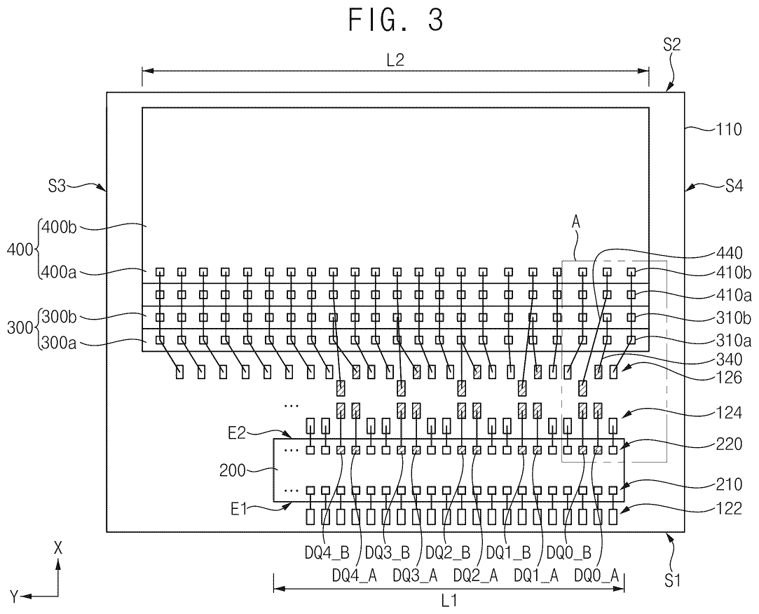

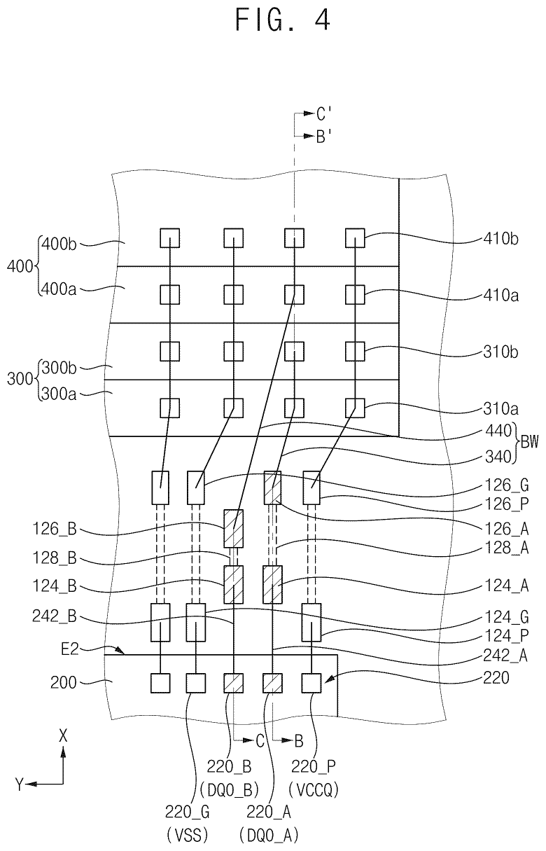

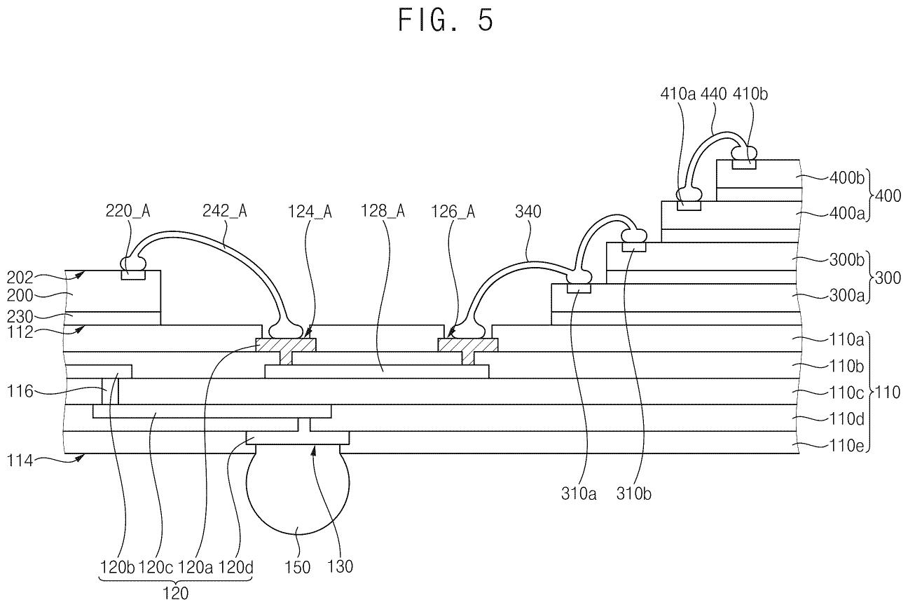

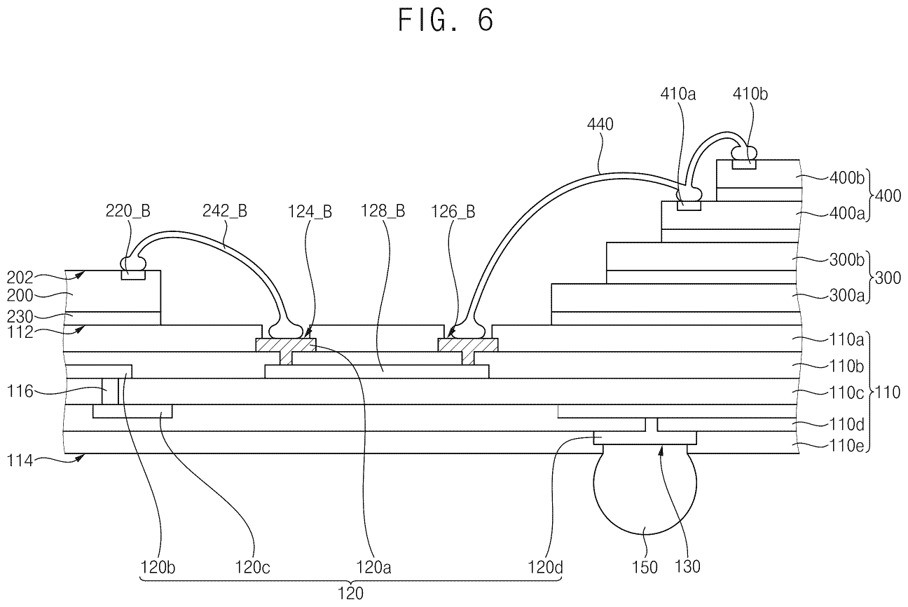

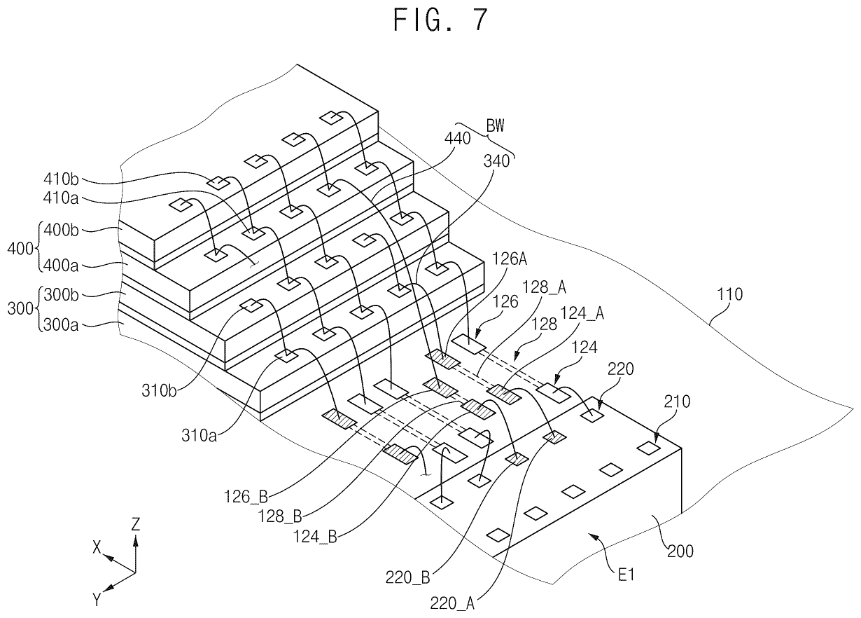

FIG. 2 is a cross-sectional view illustrating a semiconductor package in accordance with example embodiments. FIG. 3 is a plan view of the semiconductor package of FIG. 2. FIG. 4 is an enlarged plan view illustrating portion ‘A’ in FIG. 3. FIG. 5 is a cross-sectional view taken along the line B-B′ in FIG. 4. FIG. 6 is a cross-sectional view taken along the line C-C′ in FIG. 4. FIG. 7 is a perspective view illustrating portion ‘A’ in FIG. 3. FIG. 3 is a plan view illustrating the semiconductor package in FIG. 2, wherein a molding member (e.g., a sealing member 160 in FIG. 2) is omitted.

Referring to FIGS. 2, 3, 4, 5, 6, and 7, a semiconductor package 100 may include a package substrate 110, a buffer chip 200, a first group of semiconductor chips 300, a second group of semiconductor chips 400, and a sealing member 160. The semiconductor package 100 may further include conductive connection members that (electrically) connect the buffer chip 200, the first group of semiconductor chips 300, and the second group of semiconductor chips 400 to the package substrate 110. In addition, the semiconductor package 100 may further include external connection members 150. The first group of semiconductor chips 300 may include at least two lower semiconductor chips 300a and 300b (a first lower semiconductor chip 300a and a second lower semiconductor chip 300b) that are sequentially stacked on each other, and the second group of semiconductor chips 400 may include at least two upper semiconductor chips 400a and 400b (a first upper semiconductor chip 400a and a second upper semiconductor chip 400b) that are sequentially stacked on each other. In some embodiments, the first lower semiconductor chip 300a, the second lower semiconductor chip 300b, the first upper semiconductor chip 400a, and the second upper semiconductor chip 400b may be sequentially stacked.

In example embodiments, the package substrate 110 may be a substrate having an upper surface 112 and a lower surface 114 opposite to each other in a third direction (Z direction). For example, the package substrate 110 may include a printed circuit board (PCB), a flexible substrate, a tape substrate, etc. The printed circuit board may be a multilayer circuit board having vias and various circuits therein. The package substrate 110 may include substrate wirings for electrical connection among the buffer chip 200, the first group of semiconductor chips 300, and the second group of semiconductor chips 400.

The package substrate 110 may include a first side portion S1 and a second side portion S2 that extend in a first direction (Y direction) and are opposite to each other in a second direction (X direction) and may include a third side portion S3 and a fourth side portion S4 that extend in the second direction (X direction) and are opposite to each other in the first direction (Y direction). The first direction and the second direction may intersect with (may be perpendicular to) each other.

The package substrate 110 may include upper substrate pads that are exposed from the upper surface 112 of the package substrate 110. The upper substrate pads may include external channel substrate pads 122, buffer-side internal channel substrate pads 124, and memory-side internal channel substrate pads 126.

The external channel substrate pads 122 may be arranged to be spaced apart from each other in the first direction (Y direction) along the first side portion S1 of the package substrate 110. The external channel substrate pads 122 may be arranged to be adjacent to a first side E1 of the buffer chip 200. The buffer-side internal channel substrate pads 124 may be arranged to be adjacent to a second side E2 of the buffer chip 200 opposite to the first side E1 (in the second direction (X direction)). The buffer-side internal channel substrate pads 124 may be arranged to be spaced apart from each other in the first direction (Y direction). The memory-side internal channel substrate pads 126 may be arranged adjacent to one side (e.g., a side facing the second side E2 of the buffer chip 200 in the second direction (X direction)) of the lowermost semiconductor chip (e.g., the first lower semiconductor chip 300a) of the first group of semiconductor chips 300. The memory-side internal channel substrate pads 126 may be arranged to be spaced apart from each other in the first direction (Y direction). The memory-side internal channel substrate pads 126 may be arranged to be spaced apart from the corresponding buffer-side internal channel substrate pads 124 in the second direction (X direction) so as to correspond to the buffer-side internal channel substrate pads 124, respectively. The memory-side internal channel substrate pads 126 may be (electrically) connected to the buffer-side internal channel substrate pads 124, respectively, by the substrate wirings.

The buffer-side internal channel substrate pads 124 may be arranged in a zigzag shape along the first direction (Y direction). For example, some (e.g., at least one) of the buffer-side internal channel substrate pads 124 may be spaced apart from the first side E1 of the buffer chip 200 by a first distance (in the second direction (X direction)), and others (e.g., at least another one) of the buffer-side internal channel substrate pads 124 may be spaced apart from the first side E1 of the buffer chip 200 by a second distance (in the second direction (X direction)) greater than the first distance. Alternatively, the buffer-side internal channel substrate pads 124 may be arranged in a straight line (with the same distance from the first side E1 of the buffer chip 200 in the second direction (X direction)) along a line parallel to the first direction (Y direction).

The memory-side internal channel substrate pads 126 may be arranged in a zigzag shape along the first direction (Y direction). For example, some (e.g., at least one) of the memory-side internal channel substrate pads 126 may be spaced apart from one side (e.g., the side facing the second side E2 of the buffer chip 200 in the second direction (X direction)) of the lowermost semiconductor chip (e.g., the first lower semiconductor chip 300a) among the first group of semiconductor chips 300 by a third distance (in the second direction (X direction)), and others (e.g., at least another one) of the memory-side internal channel substrate pads 126 may be spaced apart from one side (e.g., the side facing the second side E2 of the buffer chip 200 in the second direction (X direction)) of the lowermost semiconductor chip (e.g., the first lower semiconductor chip 300a) by a fourth distance (in the second direction (X direction)) greater than the third distance. Alternatively, the memory-side internal channel substrate pads 126 may be arranged in a straight line (with the same distance from the side of the first lower semiconductor chip 300a facing the second side E2 of the buffer chip 200 in the second direction (X direction)) along a line parallel to the first direction (Y direction).

Although only a few upper substrate pads (e.g., the external channel substrate pads 122, the buffer-side internal channel substrate pads 124, and the memory-side internal channel substrate pads 126) are illustrated in the figures, it will be understood that the number, shape, and arrangement of the upper substrate pads are provided by way of example and that the present inventive concept is not limited thereto.

In example embodiments, the buffer chip 200 may be disposed on the upper surface 112 of the package substrate 110. The buffer chip 200 may be attached to the upper surface 112 of the package substrate 110 by an adhesive film 230. The adhesive film 230 may include a die attach film (DAF). The buffer chip 200 may be arranged such that a second surface (inactive surface) opposite to a first surface (active surface) 202 on which buffer chip pads 210 and 220 are formed faces the package substrate 110 (in the third direction (Z direction)). The buffer chip 200 may be stacked on the package substrate 110 such that the first surface 202 on which the buffer chip pads 210 and 220 are formed faces upward.

The buffer chip 200 may have a rectangular shape with four sides when viewed from plan view. The buffer chip 200 may include the first side E1 and the second side E2 that extend in a direction parallel to the first direction (Y direction) and face each other (in the second direction (X direction)). The first side E1 of the buffer chip 200 may be arranged adjacent to the first side portion S1 of the package substrate 110. A length L1 in the first direction (Y direction) of the buffer chip 200 may be within a range of (about) 4 millimeters (mm) to (about) 8 mm.

The buffer chip pads 210 and 220 of the buffer chip 200 may include external channel buffer pads 210 and internal channel buffer pads 220. The external channel buffer pads 210 may be spaced apart from each other along the first side E1 of the buffer chip 200 on an upper surface (the first surface (the active surface)) of the buffer chip 200. The internal channel buffer pads 220 may be spaced apart from each other along the second side E2 of the buffer chip 200 on the upper surface of the buffer chip 200.

The internal channel buffer pads 220 may be arranged in a straight line along a line parallel to the first direction (Y direction). Alternatively, the internal channel buffer pads 220 may be arranged in a zigzag shape along the first direction (Y direction). For example, some (e.g., at least one) of the internal channel buffer pads 220 may be spaced apart from the second side E2 of the buffer chip 200 by a fifth distance (in the second direction (X direction)), and others (e.g., at least another one) of the internal channel buffer pads 220 may be spaced apart from the second side E2 of the buffer chip 200 by a sixth distance (in the second direction (X direction)) greater than the fifth distance.

The buffer chip 200 may be (electrically) connected to the package substrate 110 by first bonding wires as the conductive connection members. The first bonding wires may include external channel bonding wires 240 and internal channel bonding wires 242. The external channel bonding wires 240 may (electrically) connect the external channel buffer pads 210 of the buffer chip 200 to the external channel substrate pads 122 of the package substrate 110. The internal channel bonding wires 242 may (electrically) connect the internal channel buffer pads 220 of the buffer chip 200 to the buffer-side internal channel substrate pads 124 of the package substrate 110.

In example embodiments, the first group of semiconductor chips 300 may be arranged on the upper surface 112 of the package substrate 110. The first lower semiconductor chip 300a of the first group of semiconductor chips 300 may be attached to the package substrate 110 by an adhesive film 330a. The second lower semiconductor chip 300b of the first group of semiconductor chips 300 may be attached to the first lower semiconductor chip 300a by an adhesive film 330b. The second group of semiconductor chips 400 may be arranged on the first group of semiconductor chips 300. The first upper semiconductor chip 400a of the second group of semiconductor chips 400 may be attached to the uppermost chip (e.g., the second lower semiconductor chip 300b) among the first group of semiconductor chips 300 by an adhesive film 430a. The second upper semiconductor chip 400b of the second group of semiconductor chips 400 may be attached to the first upper semiconductor chip 400a by an adhesive film 430b.

The adhesive films 330a, 330b, 430a, and 430b may include a die attach film DAF. For example, each of the first and second lower semiconductor chips 300a and 300b and the first and second upper semiconductor chips 400a and 400b may have a thickness within a range of (about) 40 micrometers (μm) to (about) 110 μm. The thickness of each of the adhesive films 330a, 330b, 430a, and 430b may be within a range of (about) 10 μm to (about) 60 μm.

The first lower semiconductor chip 300a may be arranged such that a second surface (inactive surface) opposite to a first surface (active surface) on which chip pads 310a are formed faces the package substrate 110 (in the third direction (Z direction)). The first lower semiconductor chip 300a may be stacked on the package substrate 110 such that the first surface on which the chip pads 310a of the first lower semiconductor chip 300a are formed faces upward.

The second lower semiconductor chip 300b may be stacked on the first lower semiconductor chip 300a in a cascade structure. For example, the second lower semiconductor chip 300b may be offset on the first lower semiconductor chip 300a in the second direction (X direction). Herein, being offset may mean arranging two or more stacked elements to have portions that do not overlap with each other in the third direction (Z direction). For example, (hypothetical) center lines of the two or more stacked elements with respect to the first direction (Y direction) and/or the second direction (X direction) may not be aligned with each other in the third direction (Z direction). For example, a portion of an upper surface of the first lower semiconductor chip 300a may be exposed without overlapping the second lower semiconductor chip 300b in the third direction (Z direction). The second lower semiconductor chip 300b may be offset in the second direction (X direction) such that the chip pads 310a of the first lower semiconductor chip 300a are exposed (not overlapped with the second lower semiconductor chip 300b in the third direction (Z direction)).

The first upper semiconductor chip 400a may be stacked on the second lower semiconductor chip 300b in a cascade structure. The first upper semiconductor chip 400a may be offset on the second lower semiconductor chip 300b in the second direction (X direction). For example, a portion of an upper surface of the second lower semiconductor chip 300b may be exposed from the first upper semiconductor chip 400a. The first upper semiconductor chip 400a may be offset on the second lower semiconductor chip 300b in the second direction (X direction) such that the chip pads 310b of the second lower semiconductor chip 300b are exposed (not overlapped with the first upper semiconductor chip 400a in the third direction (Z direction)).

The second upper semiconductor chip 400b may be stacked on the first upper semiconductor chip 400a in a cascade structure. The second upper semiconductor chip 400b may be offset on the first upper semiconductor chip 400a in the second direction (X direction). For example, a portion of an upper surface of the first upper semiconductor chip 400a may be exposed from the second upper semiconductor chip 400b. The second upper semiconductor chip 400b may be offset in the second direction (X direction) such that chip pads 410a of the first upper semiconductor chip 400a are exposed (not overlapped with the second upper semiconductor chip 400b in the third direction (Z direction)).

The first lower semiconductor chip 300a, the second lower semiconductor chip 300b, the first upper semiconductor chip 400a, and the second upper semiconductor chip 400b may have the same shape (and/or equal size). The first and second lower semiconductor chips 300a and 300b and the first and second upper semiconductor chips 400a and 400b may have a rectangular shape having four sides when viewed from plan view. Each of the first and second lower semiconductor chips 300a and 300b and the first and second upper semiconductor chips 400a and 400b may include a third side and a fourth side that extend in a direction parallel to the first direction (Y direction) and opposite to each other in the second direction (X direction)). The third side of each of the first and second lower semiconductor chips 300a and 300b and the first and second upper semiconductor chips 400a and 400b may be arranged adjacent (closer than the fourth side thereof) to the first side portion S1 of the package substrate 110. A length L2 in the first direction (Y direction) of each of the first and second lower semiconductor chips 300a and 300b and the first and second upper semiconductor chips 400a and 400b may be within a range of (around) 10 mm to (around) 14 mm.

In example embodiments, the first group of semiconductor chips 300 and the second group of semiconductor chips 400 may be (electrically) connected to the package substrate 110 by second bonding wires BW as the conductive connection members. The second bonding wires BW may (electrically) connect the chip pads 310a, 310b, 410a, and 410b of the first group of semiconductor chips 300 and the second group of semiconductor chips 400 to the memory-side internal channel substrate pads 126 of the package substrate 110.

As illustrated in FIGS. 3 and 4, the internal channel buffer pads 220 may include first channel buffer pads 220_A and second channel buffer pads 220B that are (alternately) arranged in the first direction (Y direction). In some embodiments, the first channel buffer pad 220_A and the second channel buffer pad 220B may be adjacent to each other in the first direction (Y direction). A pair of the first channel buffer pad 220_A and the second channel buffer pad 220B may be between the ground pad 220_G and the power pad 220_P in the first direction (Y direction). The first channel buffer pads 220_A may be data signal pads for transmitting a data signal through the first internal channel A. The second channel buffer pads 220B may be data signal pads for transmitting a data signal through the second internal channel B. When there are eight signals (DQ0_A, DQ1_A, . . . , DQ7_A) for the first internal channel A and eight signals (DQ0_B, DQ1_B, . . . . DQ7_B) for the second internal channel B, the sixteen (16) first and second channel buffer pads 220A and 220B (eight pairs of the first and second channel buffer pads 220A and 220B) may be arranged (alternately) in the first direction (Y direction) for DQ0_A, DQ0_B, DQ1_A, DQ1_B, . . . , DQ7_A, and DQ7_B. For example, a first one of the first channel buffer pads 220_A for DQ0_A, a first one of the second channel buffer pads 220_B for DQ0_B, a second one of the first channel buffer pads 220_A for DQ1_A, a second one of the second channel buffer pads 220_B for DQ1_B, a third one of the first channel buffer pads 220_A for DQ2_A, a third one of the second channel buffer pads 220_B for DQ2_B, a fourth one of the first channel buffer pads 220_A for DQ3_A, a fourth one of the second channel buffer pads 220_B for DQ3_B, a fifth one of the first channel buffer pads 220_A for DQ4_A, a fifth one of the second channel buffer pads 220_B for DQ4_B, a sixth one of the first channel buffer pads 220_A for DQ5_A, a sixth one of the second channel buffer pads 220_B for DQ5_B, a seventh one of the first channel buffer pads 220_A for DQ6_A, a seventh one of the second channel buffer pads 220_B for DQ6_B, an eighth one of the first channel buffer pads 220_A for DQ7_A, and an eighth one of the second channel buffer pads 220_B for DQ7_B may be sequentially arranged in the first direction (Y direction).

The buffer-side internal channel substrate pads 124 (electrically) connected to the internal channel buffer pads 220 by the internal channel bonding wires 242 may include first channel buffer-side pads 124_A and second channel buffer-side pads 124_B that are (alternately) arranged in the first direction (Y direction). For example, pairs comprising one of the first channel buffer-side pads 124_A and one of the second channel buffer-side pads 124_B may be arranged in the first direction (Y direction). The internal channel bonding wires 242 may include first channel buffer-side wires 242_A and second channel buffer-side wires 242_B. The first channel buffer-side wires 242_A may (electrically) connect the first channel buffer pads 220_A of the buffer chip 200 to the first channel buffer-side pads 124_A of the package substrate 110 (, respectively). The second channel buffer-side wires 242_B may electrically connect the second channel buffer pads 220_B of the buffer chip 200 to the second channel buffer-side pads 124_B of the package substrate 110 (, respectively).

The memory-side internal channel substrate pads 126 (electrically) connected to the buffer-side internal channel substrate pads 124 by the substrate wirings may include first channel memory-side pads 126_A and second channel memory-side pads 126_B that are (alternately) arranged in the first direction (Y direction). For example, pairs of one of the first channel memory-side pads 126_A and one of the second channel memory-side pads 126_B may be arranged in the first direction (Y direction). The second bonding wires BW may include first channel wires 340 and second channel wires 440. The first channel wires 340 may (electrically) connect the chip pads 310a and 310b of the first group of semiconductor chips 300 to the first channel memory-side pads 126_A of the package substrate 110. The second channel wires 440 may electrically connect the chip pads 410a and 410b of the second group of semiconductor chips 400 to the second channel memory-side pads 126_B of the package substrate 110.

As illustrated in FIGS. 2, 4, 5, and 6, the buffer-side internal channel substrate pads 124 and the memory-side internal channel substrate pads 126 may be electrically connected to each other in one-to-one correspondence. The first channel buffer-side pads 124_A and the first channel memory-side pads 126_A may be electrically connected to each other in one-to-one correspondence by first internal wirings 128_A. The second channel buffer-side pads 124_B and the second channel memory-side pads 126_B may be electrically connected to each other in one-to-one correspondence by second internal wirings 128_B. The first internal wirings 128_A and the second internal wirings 128_B may be arranged (alternately) in the first direction (Y direction). For example, pairs of one of the first internal wirings 128_A and one of the second internal wirings 128_B may be arranged in the first direction (Y direction). The first internal wirings 128_A and the second internal wirings 128_B may be arranged on the same circuit layer. The first internal wirings 128_A and the second internal wirings 128_B may extend parallel to each other. For example, the first internal wirings 128_A and the second internal wirings 128_B may extend in directions parallel to the second direction (X direction). The first internal wires 128_A and the second internal wires 128_B may extend so as not to intersect each other in the same circuit layer.

In particular, the package substrate 110 may include first, second, third, fourth, and fifth insulating layers 110a, 110b, 110c, 110d, and 110e. The first insulating layer 110a may be an upper protective layer, the second insulating layer 110b may be an upper insulating layer, the third insulating layer 110c may be a core layer, the fourth insulating layer 110d may be a lower insulating layer, and the fifth insulating layer 110e may be a lower protective layer. In some embodiments, the lower protective layer, the lower insulating layer, the core layer, the upper insulating layer, and the upper protective layer may be sequentially stacked.

The third insulating layer 110c as the core layer may include a non-conductive material layer. The third insulating layer 110c may include a reinforced polymer, etc. The third insulating layer 110c may serve as a boundary dividing upper and lower portions of the package substrate 110.

A second wiring 120b may be formed on an upper surface of the third insulating layer 110c. The second insulating layer 110b may be on (e.g., may cover or overlap) the second wiring 120b. A first wiring 120a may be formed on an upper surface of the second insulating layer 110b and may be (electrically) connected to the second wiring 120b through an opening formed in the second insulating layer 110b. A third wiring 120c may be formed on a lower surface of the third insulating layer 110c. The fourth insulating layer 110d may be on (e.g., may cover or overlap) the third wiring 120c on the lower surface of the third insulating layer 110c. A fourth wiring 120d may be formed on a lower surface of the fourth insulating layer 110d and may be (electrically) connected to the third wiring 120c through an opening formed in the fourth insulating layer 110d.

The first, second, third, and fourth wirings 120a, 120b, 120c, and 120d may be first, second, third, and fourth circuit layers stacked in a thickness direction (Z direction) from an upper portion (e.g., a portion closer to the upper surface 112) of the package substrate 110 toward a lower portion (e.g., a portion closer to the lower surface 114) of the package substrate 110. A conductive through via 116 may extend in (e.g., penetrate) the third insulating layer 110c as the core layer to (electrically) connect the second wiring 120b and the third wiring 120c. For example, the wiring 120 (e.g., the first, second, third, and fourth wirings 120a, 120b, 120c, and 120d) may include a metal material such as copper, aluminum, etc. It will be understood that the arrangements and numbers of the insulating layers (e.g., the first, second, third, fourth, and fifth insulating layers, 110a, 110b, 110c, 110d, and 110e) and the wirings 120 are provided as examples, and the present inventive concept is not limited thereto.

The first insulating layer 110a as the upper protective layer may be formed in the upper surface 112 of the package substrate 110, and the first insulating layer 110a may expose at least a portion of the first wiring 120a. For example, the upper surface 112 of the package substrate 110 may be an upper surface of the first insulating layer 110a. The exposed portion of the first wiring 120a may be provided as the upper substrate pad (e.g., the external channel substrate pads 122, the buffer-side internal channel substrate pads 124, and the memory-side internal channel substrate pads 126). The fifth insulating layer 110e as the lower protective layer may be formed in the lower surface 114 of the package substrate 110, and the fifth insulating layer 110e may expose at least a portion of the fourth wiring 120d. For example, the lower surface 114 of the package substrate 110 may be a lower surface of the fifth insulating layer 110e. The exposed portion of the fourth wiring 120d may be provided as a lower substrate pad 130.

As illustrated in FIGS. 5, 6, and 7, the first channel buffer-side pad 124_A and the first channel memory-side pad 126_A may be (electrically) connected to each other by the first internal wiring 128_A. The second channel buffer-side pad 124_B and the second channel memory-side pad 126_B may be (electrically) connected to each other by the second internal wiring 128_B. The first internal wiring 128_A and the second internal wiring 128_B may be portions of the second wirings 120b provided in (as) the same second circuit layer.

The first channel buffer pad 220_A, the first channel buffer-side pad 124_A, and the first channel memory-side pad 126_A may constitute a portion of the first internal channel A for transmitting data signals between the buffer chip 200 and the first group of semiconductor chips 300. The second channel buffer pad 220_B, the second channel buffer-side pad 124_B, and the second channel memory-side pad 126_B may constitute a portion of the second internal channel B for transmitting data signals between the buffer chip 200 and the second group of semiconductor chips 400.

In example embodiments, the internal channel buffer pads 220 of the buffer chip 200 may further include power pads 220_P and/or ground pads 220_G that are arranged between (pairs of) the first and second channel buffer pads 220_A and 220_B. The buffer-side internal channel substrate pads 124 may further include power buffer-side pads 124_P and ground buffer-side pads 124_G. The memory-side internal channel substrate pads 126 may further include power memory-side pads 126_P and ground memory-side pads 126_G. The power buffer-side pads 124_P and the power memory-side pads 126_P may be (electrically) connected to each other by the substrate wirings (in the package substrate 110). The ground buffer-side pads 124_G and the ground memory-side pads 126_G may be (electrically) connected to each other by the substrate wirings (in the package substrate 110).

The power pads 220_P and the ground pads 220_G of the buffer chip 200 may be (electrically) connected to the power buffer-side pads 124_P and the ground buffer-side pads 124_G of the package substrate 110 by the internal channel bonding wires 242. The chip pads 310a, 310b, 410a, and 410b of the first and second groups of semiconductor chips 300 and 400 may be (electrically) connected to the power memory-side pads 126_P and the ground memory-side pads 126_G by the second bonding wires BW.

Accordingly, power signals may be transmitted between the buffer chip 200 and the first and second groups of semiconductor chips 300 and 400 through the power pads 220_P, the power buffer-side pads 124_P, and the power memory-side pads 126_P. Ground signals may be transmitted between the buffer chip 200 and the first and second groups of semiconductor chips 300 and 400 through the ground pads 220_G, the ground buffer-side pads 124_G, and the ground memory-side pads 126_G.

In example embodiments, the sealing member 160 may be on (e.g., may cover or overlap) the buffer chip 200, the first and second groups of semiconductor chips 300 and 400, the first bonding wires 240 and 242, and the second bonding wires 340 and 440 on the upper surface 112 of the package substrate 110. The sealing member 160 may include a thermosetting resin, for example, an epoxy mold compound (EMC).

In example embodiments, the lower substrate pads 130 for providing an electrical signal may be formed on the lower surface 114 of the package substrate 110. An external connection member 150 for electrical connection with an external device may be disposed on the lower substrate pad 130 of the package substrate 110. For example, the external connection member 150 may be a solder ball. The semiconductor package 100 may be mounted on a module substrate of a storage device via the solder balls to form a memory module.

The lower substrate pad 130 and the external channel substrate pad 122 may be (electrically) connected to each other by the substrate wiring to form (a portion of) the external channel CH0. Accordingly, the buffer chip 200 may be (electrically) connected to an external host (e.g., the host 20) through the external channel CH0.

As mentioned above, the semiconductor package 100 may include the first group of semiconductor chips 300 arranged on the package substrate 110, the second group of semiconductor chips 400 stacked on the first group of semiconductor chips 300, and the buffer chip 200 configured to (selectively) connect (e.g., electrically connect) one of the first and second internal channels A and B that are respectively (electrically) connected to the first and second groups of semiconductor chips 300 and 400. The first channel buffer pads 220_A for the first internal channel A and the second channel buffer pads 220_B for the second internal channel B of the buffer chip 200 may be (alternately) arranged in the first direction (Y direction). The first channel buffer pads 220_A and the second channel buffer pads 220_B may be adjacent to each other in the first direction (Y direction). For example, a pair of the first and second channel buffer pads 220_A and 220_B may be between the power pads 220_P and the ground pads 220_G in the first direction (Y direction).

The package substrate 110 may include the first channel buffer-side pads 124_A and the first channel memory-side pads 126_A for (electrically) connecting the first channel buffer pads 220_A and the chip pads 310a and 310b of the first group of semiconductor chips 300, and the second channel buffer-side pads 124_B and the second channel memory-side pads 126_B for (electrically) connecting the second channel buffer pads 220_B and the chip pads 410a and 410b of the second group of semiconductor chips 400.

Since the first and second channel buffer pads 220_A and 220_B are arranged alternately (e.g., paired with each other) in the first direction (Y direction), the first and second channel buffer-side pads 124_A and 124_B may also be arranged alternately (e.g., paired with each other) and the first and second channel memory-side pads 126_A and 126_B may also be arranged alternately (e.g., paired with each other). Accordingly, the first internal wirings 128_A that (electrically) connect the first channel buffer-side pads 124_A and the first channel memory-side pads 126_A and the second internal wirings 128_B that (electrically) connect the second channel buffer-side pads 124_B and the second channel memory-side pads 126_B may be arranged alternately (e.g., paired with each other) in the first direction (Y direction), so that the first internal wirings 128_A and the second internal wirings 128_B may be arranged on the same circuit layer. In some embodiments, one of the first channel buffer pads 220_A, a corresponding one of the first channel buffer-side pads 124_A, and a corresponding one of the first channel memory-side pads 126_A may correspond to (may be arranged or overlap) each other in the second direction (X direction). In some embodiments, one of the second channel buffer pads 220_B, a corresponding one of the second channel buffer-side pads 124_B, and a corresponding one of the second channel memory-side pads 126_B may correspond to (may be arranged or overlap) each other in the second direction (X direction).

In a comparative example, the first channel buffer pads 220_A for the first internal channel A and the second channel buffer pads 220_B for the second internal channel B may be arranged separately from each other (e.g., may not be adjacent to each other or may not be paired with each other in the first direction (Y direction)). In this case, a portion of the first internal wirings 128_A and a portion of the second internal wirings 128_B may extend to cross each other for connection with the first and second groups of semiconductor chips 300 and 400, and accordingly, the first internal wirings 128_A and the second internal wirings 128_B must be formed on different circuit layers, which may cause a problem in that the number of circuit layers for routing increases.

In example embodiments, the buffer chip 200 may alternately arrange the data pads (e.g., the first and second channel buffer pads 220_A and 220_B) for different internal channels (e.g., the first and second internal channels A and B) to provide a routing space for an optimized routing design.

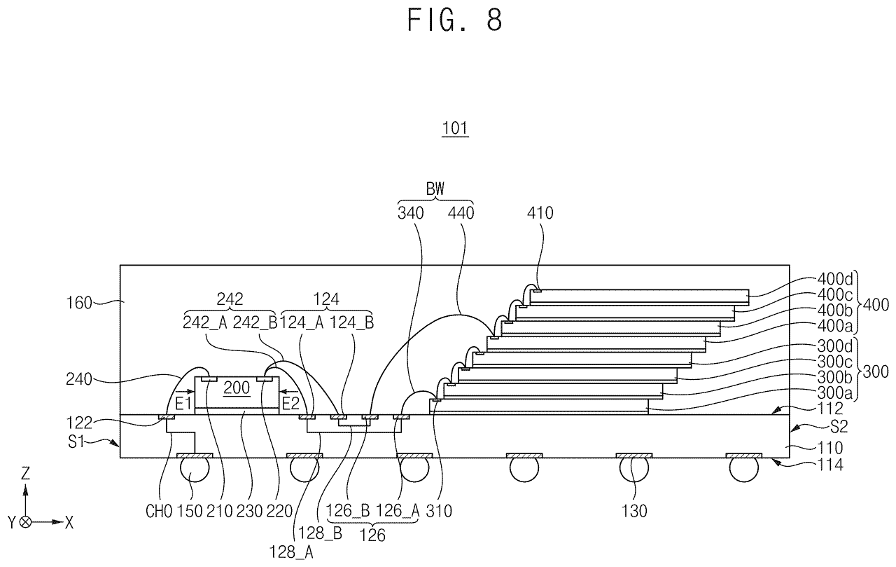

FIG. 8 is a cross-sectional view illustrating a semiconductor package in accordance with example embodiments. The semiconductor package (the semiconductor package 101) may be substantially the same as the semiconductor package (the semiconductor package 100) described with reference to FIGS. 1 and 2 except for arrangements and the numbers of a first group of semiconductor chips (the first group of semiconductor chips 300) and a second group of semiconductor chips (the second group of semiconductor chips 400). Thus, same reference numerals may be used to refer to the same or like elements unless clearly described otherwise and any further repetitive explanation concerning the above elements may be omitted.

Referring to FIG. 8, a semiconductor package 101 may include a first group of semiconductor chips 300 arranged on an upper surface 112 of a package substrate 110, and a second group of semiconductor chips 400 arranged on the first group of semiconductor chips 300. The first group of semiconductor chips 300 may include first, second, third, and fourth lower semiconductor chips 300a, 300b, 300c, and 300d sequentially stacked on the upper surface 112 of the package substrate 110. The second group of semiconductor chips 400 may include first, second, third, and fourth upper semiconductor chips 400a, 400b, 400c, and 400d sequentially stacked on the uppermost lower semiconductor chip (e.g., the fourth lower semiconductor chip 300d) among the first group of semiconductor chips 300.

In example embodiments, the first, second, third, and fourth lower semiconductor chips 300a, 300b, 300c, and 300d of the first group of semiconductor chips 300 may be sequentially offset in the second direction (X direction) on the package substrate 110. Each of the first, second, third, and fourth lower semiconductor chips 300a, 300b, 300c, and 300d may be stacked such that a first surface (e.g., an upper surface of each of the first, second, third, and fourth lower semiconductor chips 300a, 300b, 300c, and 300d) on which chip pads 310 are formed faces upward. The first, second, third, and fourth upper semiconductor chips 400a, 400b, 400c, and 400d of the second group of semiconductor chips 400 may be sequentially offset in the second direction (X direction). Each of the first, second, third, and fourth upper semiconductor chips 400a, 400b, 400c, and 400d may be stacked such that a first surface (e.g., an upper surface of each of the first, second, third, and fourth upper semiconductor chips 400a, 400b, 400c, and 400d) on which chip pads 410 are formed faces upward.

In example embodiments, the first group of semiconductor chips 300 and the second group of semiconductor chips 400 may be (electrically) connected to the package substrate 110 by second bonding wires BW as conductive connection members. The second bonding wires BW may (electrically) connect the chip pads 310 and 410 of the first group of semiconductor chips 300 and the second group of semiconductor chips 400 to memory-side internal channel substrate pads 126 of the package substrate 110.

The memory-side internal channel substrate pads 126 may include first channel memory-side pads 126_A and second channel memory-side pads 126_B that are (alternately) arranged in a first direction (Y direction). In some embodiments, pairs of the first channel memory-side pad 126_A and the second channel memory-side pad 126_B may be arranged in the first direction (Y direction). The second bonding wires BW may include first channel wires 340 and second channel wires 440. The first channel wires 340 may (electrically) connect the chip pads 310 of the first group of semiconductor chips 300 to the first channel memory-side pads 126_A of the package substrate 110. The second channel wires 440 may (electrically) connect the chip pads 410 of the second group of semiconductor chips 400 to the second channel memory-side pads 126_B of the package substrate 110.

A first channel buffer pad 220_A, a first channel buffer-side pad 124_A, and the first channel memory-side pad 126_A may form (at least) a portion of a first internal channel A for transmitting data signals between the buffer chip 200 and the first group of semiconductor chips 300. A second channel buffer pad 220_B, a second channel buffer-side pad 124_B, and the second channel memory-side pad 126_B may form (at least) a portion of a second internal channel B for transmitting data signals between the buffer chip 200 and the second group of semiconductor chips 400.

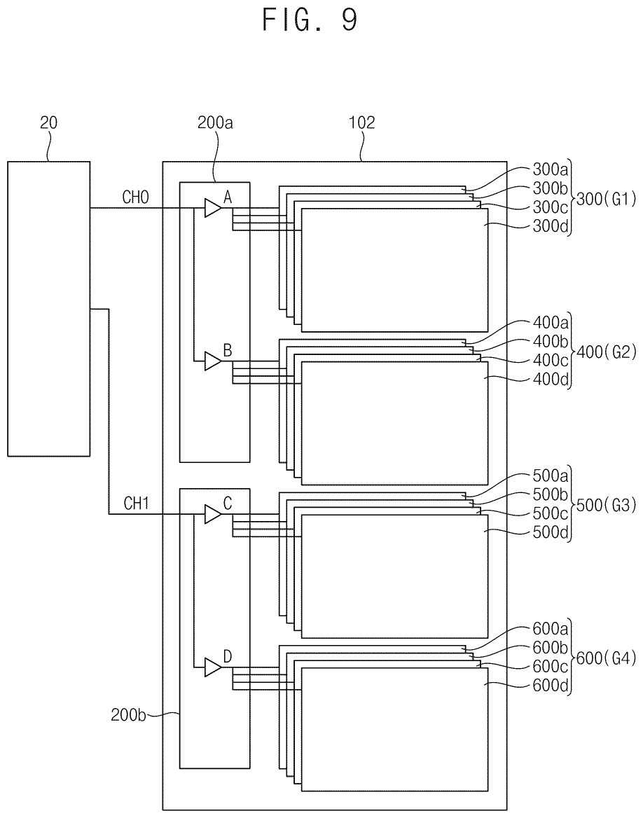

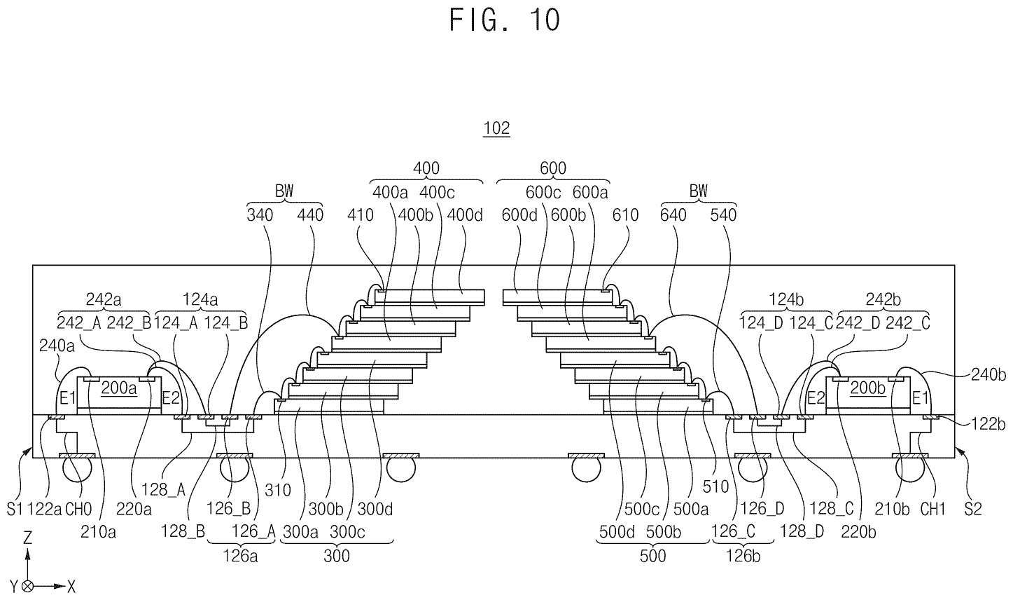

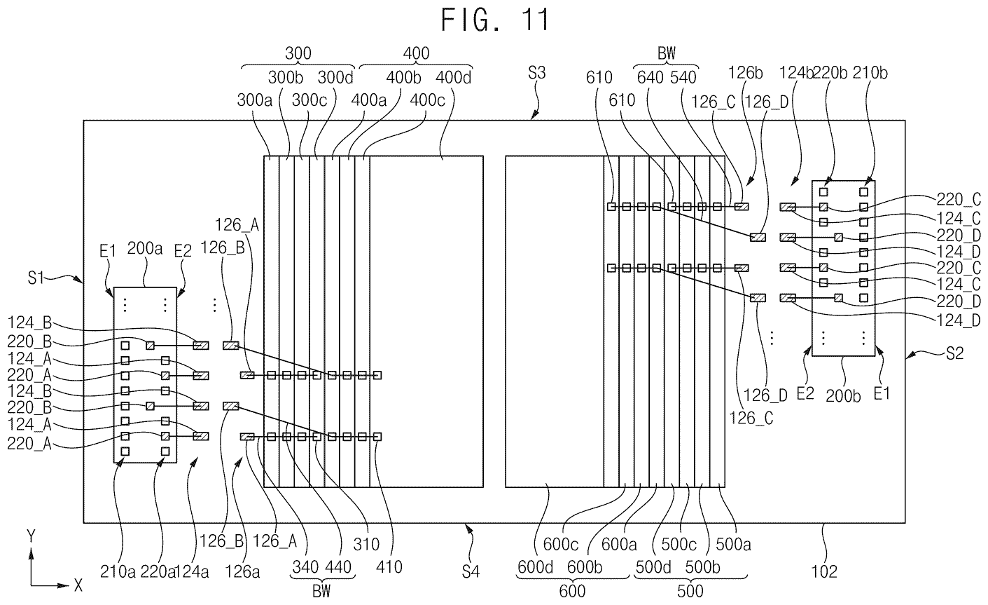

FIG. 9 is a block diagram illustrating a semiconductor package in accordance with example embodiments. FIG. 10 is a cross-sectional view illustrating the semiconductor package in FIG. 9. FIG. 11 is a plan view of the semiconductor package of FIG. 10. The semiconductor package (a semiconductor package 102) may be substantially the same as the semiconductor package (the semiconductor package 100) described with reference to FIGS. 1 and 2 except for arrangements and the numbers of first and second buffer chips and first, second, third, and fourth groups of semiconductor chips. Thus, same reference numerals may be used to refer to the same or like elements unless clearly described otherwise and any further repetitive explanation concerning the above elements may be omitted.

Referring to FIGS. 9, 10, and 11, the semiconductor package 102 may include a package substrate 110, a first buffer chip 200a, a second buffer chip 200b, a first group of semiconductor chips G1 (a first group of semiconductor chips 300), a second group of semiconductor chips G2 (a second group of semiconductor chips 400), a third group of semiconductor chips G3 (a third group of semiconductor chips 500), and a fourth group of semiconductor chips G4 (a fourth group of semiconductor chips 600). The semiconductor package 102 may be (electrically) connected to a host 20 by first and second external channels CH0 and CH1.

In example embodiments, the first buffer chip 200a may be (electrically) connected to the host 20, which may also be referred to as a controller 20 or an external controller 20, by the first external channel CH0, and the second buffer chip 200b may be (electrically) connected to the controller 20 by the second external channel CH1. The first buffer chip 200a may implement and (evenly) distribute first and second internal channels A and B as two internal I/O buses between the first and second groups of semiconductor chips G1 and G2 and the external controller 20. The second buffer chip 200b may implement and (evenly) distribute third and fourth internal channels C and D as two internal I/O buses between the third and fourth groups of semiconductor chips G3 and G4 and the external controller 20.

For example, the first group of semiconductor chips G1 and the first buffer chip 200a may be (electrically) connected to each other by the first internal channel A, and electrical signals such as data signals, control signals, etc. may be transmitted between the first group of semiconductor chips G1 and the first buffer chip 200a through the first internal channel A. The second group of semiconductor chips G2 and the first buffer chip 200a may be (electrically) connected to each other by the second internal channel B, and electrical signals such as data signals, control signals, etc. may be transmitted between the second group of semiconductor chips G2 and the first buffer chip 200a through the second internal channel B. The third group of semiconductor chips G3 and the second buffer chip 200b may be (electrically) connected to each other by the third internal channel C, and electrical signals such as data signals, control signals, etc. may be transmitted between the third group of semiconductor chips G3 and the second buffer chip 200b through the third internal channel C. The fourth group of semiconductor chips G4 and the second buffer chip 200b may be (electrically) connected to each other through the fourth internal channel D, and electrical signals such as data signals, control signals, etc. may be transmitted between the fourth group of semiconductor chips G4 and the second buffer chip 200b through the fourth internal channel D.

As illustrated in FIGS. 10 and 11, the first buffer chip 200a may be arranged adjacent to a first side portion S1 of the package substrate 110. The second buffer chip 200b may be arranged adjacent to a second side portion S2 of the package substrate 110. The first group of semiconductor chips 300 and the second group of semiconductor chips 400 may be arranged on a middle region of the package substrate 110 adjacent to the first buffer chip 200a, and the third group of semiconductor chips 500 and the fourth group of semiconductor chips 600 may be arranged on the middle region of the package substrate 110 adjacent to the second buffer chip 200b. For example, the first buffer chip 200a may be between the first side portion S1 of the package substrate 110 and the first and second groups of semiconductor chips 300 and 400 in the second direction (X direction). The second buffer chip 200b may be between the second side portion S2 of the package substrate 110, which is opposite to the first side portion S1 of the package substrate 110 in the second direction (X direction), and the third and fourth groups of semiconductor chips 500 and 600 in the second direction (X direction). The second group of semiconductor chips 400 may be stacked on the first group of semiconductor chips 300, and the fourth group of semiconductor chips 600 may be stacked on the third group of semiconductor chips 500. The first group of semiconductor chips 300 and the third group of semiconductor chips 500 may be spaced apart from each other on the upper surface 112 of the package substrate 110.

For connection with the first external channel CH0, first external channel substrate pads 122a may be spaced apart from each other in a first direction (Y direction) along the first side portion S1 of the package substrate 110. The first external channel substrate pads 122a may be arranged adjacent to a first side E1 of the first buffer chip 200a. For example, the first external channel substrate pads 122a may be between the first side E1 of the first buffer chip 200a and the first side portion S1 of the package substrate 110 in the second direction (X direction). First buffer-side internal channel substrate pads 124a may be arranged adjacent to a second side E2 of the first buffer chip 200a opposite to the first side E1 of the first buffer chip 200a (in the second direction (X direction)). The first buffer-side internal channel substrate pads 124a may be arranged to be spaced apart from each other in the first direction (Y direction). First memory-side internal channel substrate pads 126a may be arranged to be spaced apart from each other in the first direction (Y direction) so as to correspond to the first buffer-side internal channel substrate pads 124a, respectively. The first memory-side internal channel substrate pads 126a may be (electrically) connected to the first buffer-side internal channel substrate pads 124a, respectively, by substrate wirings (e.g., by first internal wirings 128_A).

For connection with the second external channel CH1, second external channel substrate pads 122b may be arranged to be spaced apart from each other in the first direction (Y direction) along the second side portion S2 of the package substrate 110. The second external channel substrate pads 122b may be arranged to be adjacent to a first side E1 of the second buffer chip 200b. For example, the second external channel substrate pads 122b may be between the first side E1 of the second buffer chip 200b and the second side portion S2 of the package substrate 110 in the second direction (X direction). Second buffer-side internal channel substrate pads 124b may be arranged to be adjacent to a second side E2 of the second buffer chip 200b opposite to the first side E1 of the second buffer chip 200b (in the second direction (X direction)). The second buffer-side internal channel substrate pads 124b may be arranged to be spaced apart from each other in the first direction (Y direction). Second memory-side internal channel substrate pads 126b may be arranged to be spaced apart from each other in the first direction (Y direction) so as to correspond to the second buffer-side internal channel substrate pads 124b, respectively. The second memory-side internal channel substrate pads 126b may be (electrically) connected to the second buffer-side internal channel substrate pads 124b, respectively, by the substrate wirings (e.g., by second internal wirings 128_B).

Buffer chip pads of the first buffer chip 200a may include first external channel buffer pads 210a and first internal channel buffer pads 220a. The first external channel buffer pads 210a may be arranged to be spaced apart from each other along the first side E1 of the first buffer chip 200a on an upper surface of the first buffer chip 200a. The first internal channel buffer pads 220a may be arranged to be spaced apart from each other along the second side E2 of the first buffer chip 200a on the upper surface of the first buffer chip 200a.

The first internal channel buffer pads 220a may include first channel buffer pads 220_A and second channel buffer pads 220_B that are alternately arranged in the first direction (Y direction). The first channel buffer pads 220_A may be data signal pads for transmitting a data signal through the first internal channel A. The second channel buffer pads 220_B may be data signal pads for transmitting a data signal through the second internal channel B. When there are eight signals (DQ0_A, DQ1_A, . . . , DQ7_A) for the first internal channel A and eight signals (DQ0_B, DQ1_B, . . . , DQ7_B) for the second internal channel B, the sixteen (16) first and second channel buffer pads 220A and 220B (eight pairs of the first and second channel buffer pads 220A and 200B) may be arranged (alternately) in the first direction (Y direction) for DQ0_A, DQ0_B, DQ1_A, DQ1_B, . . . , DQ7_A, and DQ7_B. For example, a first one of the first channel buffer pads 220_A for DQ0_A, a first one of the second channel buffer pads 220_B for DQ0_B, a second one of the first channel buffer pads 220_A for DQ1_A, a second one of the second channel buffer pads 220_B for DQ1_B, a third one of the first channel buffer pads 220_A for DQ2_A, a third one of the second channel buffer pads 220_B for DQ2_B, a fourth one of the first channel buffer pads 220_A for DQ3_A, a fourth one of the second channel buffer pads 220_B for DQ3_B, a fifth one of the first channel buffer pads 220_A for DQ4_A, a fifth one of the second channel buffer pads 220_B for DQ4_B, a sixth one of the first channel buffer pads 220_A for DQ5_A, a sixth one of the second channel buffer pads 220_B for DQ5_B, a seventh one of the first channel buffer pads 220_A for DQ6_A, a seventh one of the second channel buffer pads 220_B for DQ6_B, an eighth one of the first channel buffer pads 220_A for DQ7_A, and an eighth one of the second channel buffer pads 220_B for DQ7_B may be sequentially arranged in the first direction (Y direction).

The first channel buffer pads 220_A of the first buffer chip 200a may be (electrically) connected to first channel buffer-side pads 124_A of the package substrate 110 by first channel buffer-side wires 242_A. The second channel buffer pads 220_B of the first buffer chip 200a may be (electrically) connected to second channel buffer-side pads 124_B of the package substrate 110 by second channel buffer-side wires 242_B. The first channel buffer-side pads 124_A and the second channel buffer-side pads 124_B may be (electrically) connected to first channel memory-side pads 126_A and second channel memory-side pads 126_B (respectively) by the substrate wirings (e.g., the first internal wiring 128_A and the second internal wiring 128_B).

The buffer chip pads of the first buffer chip 200a may be arranged in a zigzag shape along the first direction (Y direction). Some (e.g., at least one) of the buffer chip pads of the first buffer chip 200a may be spaced apart from one side of the first buffer chip 200a by a first distance, and others (e.g., at least another one) of the buffer chip pads of the first buffer chip 200a may be spaced apart from the one side of the first buffer chip 200a by a second distance greater than the first distance. For example, among the first internal channel buffer pads 220a, the first channel buffer pads 220_A may be spaced apart from the second side E2 of the first buffer chip 200a by a first distance (in the second direction (X direction)), and the second channel buffer pads 220_B may be spaced apart from the second side E2 of the first buffer chip 200a by a second distance (in the second direction (X direction)) greater than the first distance.

In example embodiments, the first group of semiconductor chips 300 may include first, second, third, and fourth lower semiconductor chips 300a, 300b, 300c, and 300d that are sequentially stacked on an upper surface 112 of the package substrate 110. The second group of semiconductor chips 400 may include first, second, third, and fourth upper semiconductor chips 400a, 400b, 400c, and 400d that are sequentially stacked on the uppermost semiconductor chip (e.g., the fourth lower semiconductor chip 300d) among the first group of semiconductor chips 300.

The first, second, third, and fourth lower semiconductor chips 300a, 300b, 300c, and 300d of the first group of semiconductor chips 300 may be sequentially offset in the second direction (X direction) on the package substrate 110. Each of the first, second, third, and fourth lower semiconductor chips 300a, 300b, 300c, and 300d may be stacked such that a first surface (e.g., an upper surface of an exposed portion of each of the first, second, third, and fourth lower semiconductor chips 300a, 300b, 300c, and 300d) on which chip pads 310 are formed faces upward.

The first, second, third, and fourth upper semiconductor chips 400a, 400b, 400c, and 400d of the second group of semiconductor chips 400 may be sequentially offset in the second direction (X direction). Each of the first, second, third, and fourth upper semiconductor chips 400a, 400b, 400c, and 400d may be stacked such that a first surface (e.g., an upper surface of an exposed portion of each of the first, second, third, and fourth upper semiconductor chips 400a, 400b, 400c, and 400d) on which chip pads 410 are formed faces upward.

In example embodiments, the first group of semiconductor chips 300 and the second group of semiconductor chips 400 may be (electrically) connected to the package substrate 110 by second bonding wires BW as conductive connection members. The second bonding wires BW may include first channel wires 340 and second channel wires 440. The first channel wires 340 may (electrically) connect the chip pads 310 of the first group of semiconductor chips 300 to the first channel memory-side pads 126_A of the package substrate 110. The second channel wires 440 may (electrically) connect the chip pads 410 of the second group of semiconductor chips 400 to the second channel memory-side pads 126_B of the package substrate 110.

The first channel buffer pad 220_A, the first channel buffer-side pad 124_A, and the first channel memory-side pad 126_A may form (at least) a portion of the first internal channel A for transmitting data signals between the first buffer chip 200a and the first group of semiconductor chips 300. The second channel buffer pad 220_B, the second channel buffer-side pad 124_B, and the second channel memory-side pad 126_B may form (at least) a portion of the second internal channel B for transmitting data signals between the first buffer chip 200a and the second group of semiconductor chips 400.

In example embodiments, buffer chip pads of the second buffer chip 200b may include second external channel buffer pads 210b and second internal channel buffer pads 220b. The second external channel buffer pads 210b may be spaced apart from each other along the first side E1 of the second buffer chip 200b on an upper surface of the second buffer chip 200b. The second internal channel buffer pads 220b may be spaced apart from each other along the second side E2 of the second buffer chip 200b on the upper surface of the second buffer chip 200b.

The second internal channel buffer pads 220b may include third channel buffer pads 220_C and fourth channel buffer pads 220_D that are alternately arranged in the first direction (Y direction). In some embodiments, pairs of one of the third channel buffer pads 220_C and one of the fourth channel buffer pads 220_D may be arranged in the first direction (Y direction). The third channel buffer pads 220_C may be data signal pads for transmitting a data signal through the third internal channel C. The fourth channel buffer pads 220_D may be data signal pads for transmitting a data signal through the fourth internal channel D. When there are eight signals DQ0_C, DQ1_C, . . . , and DQ7_C for the third internal channel C and eight signals DQ0_D, DQ1_D, . . . , and DQ7_D for the fourth internal channel D, the sixteen (16) third and fourth channel buffer pads 220_C and 220_D may be arranged alternately in the first direction (Y direction) as DQ0_C, DQ0_D, DQ1_C, DQ1_D, . . . , DQ7_C, and DQ7_D. For example, a first one of the third channel buffer pads 220_C for DQ0_C, a first one of the fourth channel buffer pads 220_D for DQ0_D, a second one of the third channel buffer pads 220_C for DQ1_C, a second one of the fourth channel buffer pads 220_D for DQ1_D, a third one of the third channel buffer pads 220_C for DQ2_C, a third one of the fourth channel buffer pads 220_D for DQ2_D, a fourth one of the third channel buffer pads 220_C for DQ3_C, a fourth one of the fourth channel buffer pads 220_D for DQ3_D, a fifth one of the third channel buffer pads 220_C for DQ4_C, a fifth one of the fourth channel buffer pads 220_D for DQ4_D, a sixth one of the third channel buffer pads 220_C for DQ5_C, a sixth one of the fourth channel buffer pads 220_D for DQ5_D, a seventh one of the third channel buffer pads 220_C for DQ6_C, a seventh one of the fourth channel buffer pads 220_D for DQ6_D, an eighth one of the third channel buffer pads 220_C for DQ7_C, and an eighth one of the fourth channel buffer pads 220_D for DQ7_D may be sequentially arranged in the first direction (Y direction).

The third channel buffer pads 220_C of the second buffer chip 200b may be (electrically) connected to third channel buffer-side pads 124_C of the package substrate 110 by third channel buffer-side wires 242_C. The fourth channel buffer pads 220_D of the second buffer chip 200b may be (electrically) connected to fourth channel buffer-side pads 124_D of the package substrate 110 by fourth channel buffer-side wires 242_D. The third channel buffer-side pads 124_C and the fourth channel buffer-side pads 124_D may be (electrically) connected to third channel memory-side pads 126_C and fourth channel memory-side pads 126_D by the substrate wirings (e.g., by third internal wirings 128_C and fourth internal wirings 128_D, respectively).

The buffer chip pads of the second buffer chip 200b may be arranged in a zigzag shape along the first direction (Y direction). Some (e.g., at least one) of the buffer chip pads of the second buffer chip 200b may be spaced apart from one side of the second buffer chip 200b by a third distance (in the second direction (X direction)), and others (e.g., at least another one) of the buffer chip pads may be spaced apart from the one side by a fourth distance greater than the third distance (in the second direction (X direction)). For example, among the second internal channel buffer pads 220b, the third channel buffer pads 220_C may be spaced apart from the second side E2 of the second buffer chip 200b by a third distance (in the second direction (X direction)), and the fourth channel buffer pads 220_D may be spaced apart from the second side E2 of the second buffer chip 200b by a fourth distance greater than the third distance (in the second direction (X direction)).

In example embodiments, the third group of semiconductor chips 500 may include first, second, third, and fourth lower semiconductor chips 500a, 500b, 500c, and 500d that are sequentially stacked on the upper surface 112 of a package substrate 110. The fourth group of semiconductor chips 600 may include first, second, third, and fourth upper semiconductor chips 600a, 600b, 600c, and 600d that are sequentially stacked on the uppermost semiconductor chip (e.g., the fourth lower semiconductor chip 500d) among the third group of semiconductor chips 500.

The first, second, third, and fourth lower semiconductor chips 500a, 500b, 500c, and 500d of the third group of semiconductor chips 500 may sequentially offset in the second direction (X direction) on the package substrate 110. In some embodiments, the first, second, third, and fourth lower semiconductor chips 500a, 500b, 500c, and 500d of the third group of semiconductor chips 500 may sequentially offset in the opposite direction to the direction in which the first, second, third, and fourth lower semiconductor chips 300a, 300b, 300c, and 300d of the first group of semiconductor chips 300 are sequentially offset. For example, in a cross-sectional view, the first group of semiconductor chips 300 and the third group of semiconductor chips 500 may form a symmetrical shape (in the second direction (X direction)). Each of the first, second, third, and fourth lower semiconductor chips 500a, 500b, 500c, and 500d of the third group of semiconductor chips 500 may be stacked such that a first surface (each of upper surfaces of the first, second, third, and fourth lower semiconductor chips 500a, 500b, 500c, and 500d) on which chip pads 510 are formed faces upward.

The first, second, third, and fourth upper semiconductor chips 600a, 600b, 600c, and 600d of the fourth group of semiconductor chips 600 may be sequentially offset in the first horizontal direction (X direction). In some embodiments, the first, second, third, and fourth upper semiconductor chips 600a, 600b, 600c, and 600d of the fourth group of semiconductor chips 600 may sequentially offset in the opposite direction to the direction in which the first, second, third, and fourth upper semiconductor chips 400a, 400b, 400c, and 400d of the second group of semiconductor chips 400 are sequentially offset. For example, in a cross-sectional view, the second group of semiconductor chips 400 and the fourth group of semiconductor chips 600 may form a symmetrical shape (in the second direction (X direction)). Each of the first, second, third, and fourth upper semiconductor chips 600a, 600b, 600c, and 600d may be stacked such that a first surface (each of upper surfaces of the first, second, third, and fourth upper semiconductor chips 600a, 600b, 600c, and 600d) on which chip pads 610 are formed faces upward.

In example embodiments, the third group of semiconductor chips 500 and the fourth group of semiconductor chips 600 may be (electrically) connected to the package substrate 110 by the second bonding wires BW as conductive connection members. The second bonding wires BW may include third channel wires 540 and fourth channel wires 640. The third channel wires 540 may (electrically) connect chip pads 510 of the third group of semiconductor chips 500 to the third channel memory-side pads 126_C of the package substrate 110. The fourth channel wires 640 may (electrically) connect chip pads 610 of the fourth group of semiconductor chips 600 to the fourth channel memory-side pads 126_D of the package substrate 110.

The third channel buffer pad 220_C, the third channel buffer-side pad 124_C, and the third channel memory-side pad 126_C may form (at least) a portion of the third internal channel C for transmitting data signals between the second buffer chip 200b and the third group of semiconductor chips 500. The fourth channel buffer pad 220_D, the fourth channel buffer-side pad 124_D, and the fourth channel memory-side pad 126_D may form (at least) a portion of the fourth internal channel D for transmitting data signals between the second buffer chip 200b and the fourth group of semiconductor chips 600.

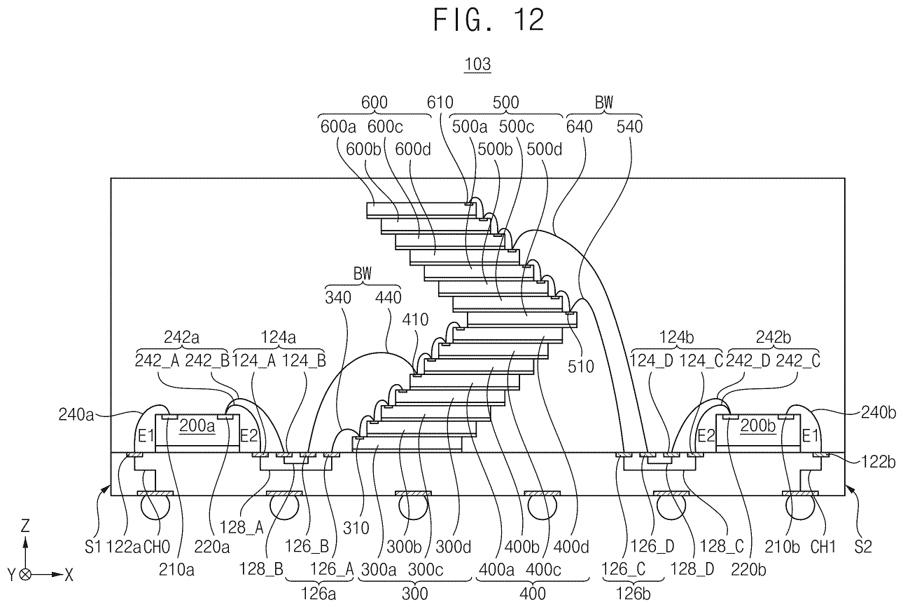

FIG. 12 is a cross-sectional view illustrating a semiconductor package in accordance with example embodiments. The semiconductor package (the semiconductor package 103) may be substantially the same as the semiconductor package (the semiconductor package 102) described with reference to FIGS. 9, 10, and 11 except for arrangements of first to fourth groups of semiconductor chips. Thus, same reference numerals may be used to refer to the same or like elements unless clearly described otherwise and any further repetitive explanation concerning the above elements may be omitted.

Referring to FIG. 12, a semiconductor package 103 may include a package substrate 110, a first buffer chip 200a, a second buffer chip 200b, a first group of semiconductor chips 300 (G1), a second group of semiconductor chips 400 (G2), a third group of semiconductor chips 500 (G3), and a fourth group of semiconductor chips 600 (G4). The semiconductor package 103 may be (electrically) connected to a host 20 by first and second external channels CH0 and CH1.

In example embodiments, the first buffer chip 200a may be arranged adjacent to a first side portion S1 of the package substrate 110. The second buffer chip 200b may be arranged adjacent to a second side portion S2 of the package substrate 110. The first group of semiconductor chips 300, the second group of semiconductor chips 400, the third group of semiconductor chips 500, and the fourth group of semiconductor chips 600 may be placed between the first and second buffer chips 200a and 200b (e.g., in the central region of the package substrate 110) in the second direction (X direction).

The first buffer chip 200a, the second buffer chip 200b, and the first group of semiconductor chips 300 may be stacked on the upper surface 112 of the package substrate 110, the second group of semiconductor chips 400 may be stacked on the first group of semiconductor chips 300, the third group of semiconductor chips 500 may be stacked on the second group of semiconductor chips 400, and the fourth group of semiconductor chips 600 may be stacked on the third group of semiconductor chips 500.

First, second, third, and fourth lower semiconductor chips 300a, 300b, 300c, and 300d of the first group of semiconductor chips 300 may be sequentially offset in the second direction (X direction) on the package substrate 110. Each of the first, second, third, and fourth lower semiconductor chips 300a, 300b, 300c, and 300d may be stacked such that a first surface (each upper surfaces of the first, second, third, and fourth lower semiconductor chips 300a, 300b, 300c, and 300d of the first group of semiconductor chips 300) on which chip pads 310 are formed faces upward.

First, second, third, and fourth upper semiconductor chips 400a, 400b, 400c, and 400d of the second group of semiconductor chips 400 may be sequentially offset in the second direction (X direction). Each of the first, second, third, and fourth upper semiconductor chips 400a, 400b, 400c, 400d may be stacked such that a first surface (each upper surfaces of the first, second, third, and fourth upper semiconductor chips 400a, 400b, 400c, and 400d of the second group of semiconductor chips 400) on which chip pads 410 are formed faces upward. In some embodiments, the first, second, third, and fourth lower semiconductor chips 300a, 300b, 300c, and 300d and the first, second, third, and fourth upper semiconductor chips 400a, 400b, 400c, and 400d may be sequentially offset in the same direction.

First, second, third, and fourth lower semiconductor chips 500a, 500b, 500c, and 500d of the third group of semiconductor chips 500 may be sequentially offset in the second direction (X direction) on the uppermost semiconductor chip (e.g., the fourth upper semiconductor chip 400d) of the second group of semiconductor chips 400. In some embodiments, the first, second, third, and fourth lower semiconductor chips 500a, 500b, 500c, and 500d may be sequentially offset in the opposite direction to the direction in which the first, second, third, and fourth lower semiconductor chips 300a, 300b, 300c, and 300d and the first, second, third, and fourth upper semiconductor chips 400a, 400b, 400c, and 400d are sequentially offset. Each of the first, second, third, and fourth lower semiconductor chips 500a, 500b, 500c, and 500d may be stacked such that a first surface (each upper surfaces of the first, second, third, and fourth lower semiconductor chips 500a, 500b, 500c, and 500d of the third group of semiconductor chips 500) on which chip pads 510 are formed faces upward.

First, second, third, and fourth upper semiconductor chips 600a, 600b, 600c, and 600d of the fourth group of semiconductor chips 600 may be sequentially offset in the second direction (X direction) on the uppermost semiconductor chip (e.g., the fourth lower semiconductor chip 500d) of the third group of semiconductor chips 500. In some embodiments, the first, second, third, and fourth lower semiconductor chips 500a, 500b, 500c, and 500d and the first, second, third, and fourth upper semiconductor chips 600a, 600b, 600c, and 600d may be sequentially offset in the same direction. Each of the first, second, third, and fourth upper semiconductor chips 600a, 600b, 600c, and 600d may be stacked such that a first surface (each upper surfaces of the first, second, third, and fourth upper semiconductor chips 600a, 600b, 600c, and 600d of the fourth group of semiconductor chips 600) on which chip pads 610 are formed faces upward.

In example embodiments, first channel buffer-side pads 124_A and first channel memory-side pads 126_A that are (electrically) connected to first channel buffer pads 220_A of the first buffer chip 200a may be arranged between the second side E2 of the first buffer chip 200a and one side (facing the second side E2 of the first buffer chip 200a in the second direction (X direction)) of the first lower semiconductor chip 300a of the first group of semiconductor chips 300. Second channel buffer-side pads 124_B and second channel memory-side pads 126_B that are (electrically) connected to second channel buffer pads 220_B of the first buffer chip 200a may be arranged between the second side E2 of the first buffer chip 200a and one side (facing the second side E2 of the first buffer chip 200a in the second direction (X direction)) of the first lower semiconductor chip 300a of the first group of semiconductor chips 300.

Third channel buffer-side pads 124_C and third channel memory-side pads 126_C that are (electrically) connected to third channel buffer pads 220_C of the second buffer chip 200b may be arranged between the second side E2 of the second buffer chip 200b and one side (facing the second side E2 of the second buffer chip 200b in the second direction (X direction)) of the first lower semiconductor chip 500a of the third group of semiconductor chips 500. Fourth channel buffer-side pads 124_D and fourth channel memory-side pads 126_D that are (electrically) connected to fourth channel buffer pads 220_D of the second buffer chip 200b may be arranged between the second side E2 of the second buffer chip 200b and one side (facing the second side E2 of the second buffer chip 200b in the second direction (X direction)) of the first lower semiconductor chip 500a of the third group of semiconductor chips 500.

In example embodiments, the first group of semiconductor chips 300 and the second group of semiconductor chips 400 may be (electrically) connected to the package substrate 110 by second bonding wires BW as conductive connection members. The second bonding wires BW may include first channel wires 340 and second channel wires 440. The first channel wires 340 may (electrically) connect the chip pads 310 of the first group of semiconductor chips 300 to the first channel memory-side pads 126_A of the package substrate 110. The second channel wires 440 may (electrically) connect the chip pads 410 of the second group of semiconductor chips 400 to the second channel memory-side pads 126_B of the package substrate 110.

The first channel buffer pad 220_A, the first channel buffer-side pad 124_A, and the first channel memory-side pad 126_A may form (at least) a portion of a first internal channel A for transmitting data signals between the first buffer chip 200a and the first group of semiconductor chips 300. The second channel buffer pad 220_B, the second channel buffer-side pad 124_B, and the second channel memory-side pad 126_B may form (at least) a portion of a second internal channel B for transmitting data signals between the first buffer chip 200a and the second group of semiconductor chips 400.

In example embodiments, the third group of semiconductor chips 500 and the fourth group of semiconductor chips 600 may be (electrically) connected to the package substrate 110 by the second bonding wires BW as conductive connection members. The second bonding wires BW may include third channel wires 540 and fourth channel wires 640. The third channel wires 540 may (electrically) connect the chip pads 510 of the third group of semiconductor chips 500 to the third channel memory-side pads 126_C of the package substrate 110. The fourth channel wires 640 may (electrically) connect the chip pads 610 of the fourth group of semiconductor chips 600 to the fourth channel memory-side pads 126_D of the package substrate 110.

The third channel buffer pad 220_C, the third channel buffer-side pad 124_C, and the third channel memory-side pad 126_C may form (at least) a portion of a third internal channel C for transmitting data signals between the second buffer chip 200b and the third group of semiconductor chips 500. The fourth channel buffer pad 220_D, the fourth channel buffer-side pad 124_D, and the fourth channel memory-side pad 126_D may form (at least) a portion of a fourth internal channel D for transmitting data signals between the second buffer chip 200b and the second group of semiconductor chips 600.

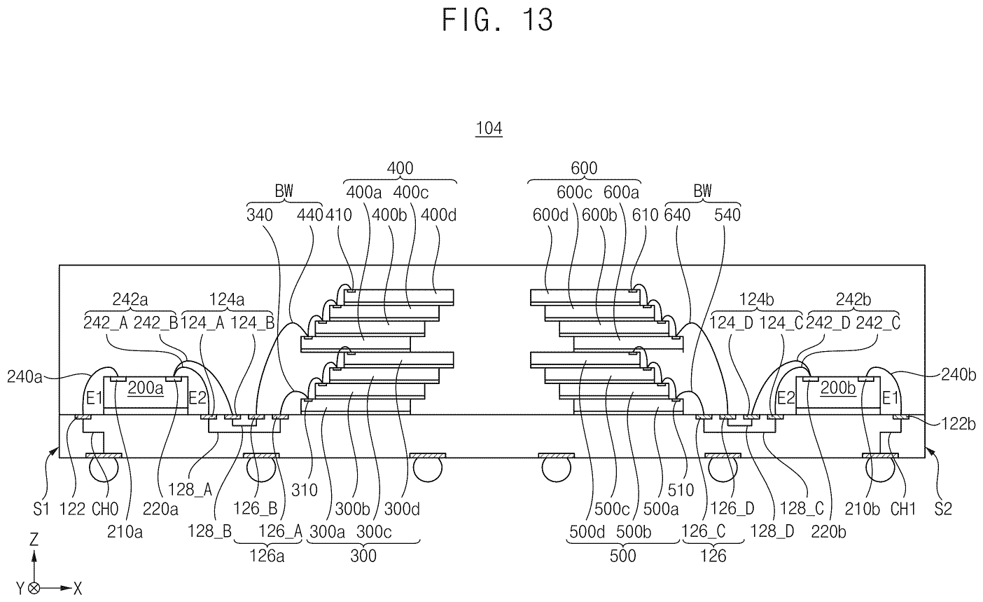

FIG. 13 is a cross-sectional view illustrating a semiconductor package in accordance with example embodiments. The semiconductor package (the semiconductor package 104) may be substantially the same as the semiconductor package (the semiconductor package 102) described with reference to FIGS. 9, 10, and 11 except for arrangements of first to fourth groups of semiconductor chips. Thus, same reference numerals may be used to refer to the same or like elements unless clearly described otherwise and any further repetitive explanation concerning the above elements may be omitted.

Referring to FIG. 13, a semiconductor package 104 may include a package substrate 110, a first buffer chip 200a, a second buffer chip 200b, a first group of semiconductor chips 300 (G1), a second group of semiconductor chips 400 (G2), a third group of semiconductor chips 500 (G3), and a fourth group of semiconductor chips 600 (G4). The semiconductor package 104 may be (electrically) connected to a host 20 by first and second external channels CH0 and CH1.

In example embodiments, the first buffer chip 200a may be arranged adjacent to a first side portion S1 of the package substrate 110. The second buffer chip 200b may be arranged adjacent to a second side portion S2 (opposite to the first side portion S1 in the second direction (X direction)) of the package substrate 110. The first group of semiconductor chips 300 and the second group of semiconductor chips 400 may be arranged on a middle region of the package substrate 110 adjacent to the first buffer chip 200a, and the third group of semiconductor chips 500 and the fourth group of semiconductor chips 600 may be arranged on the middle region of the package substrate 110 adjacent to the second buffer chip 200b. The first, second, third, and fourth groups of semiconductor chips 300, 400, 500, and 600 may be between the first buffer chip 200a and the second buffer chip 200b in the second direction (X direction). The first and second groups of semiconductor chips 300 and 400 may be between the first buffer chip 200a and the third and fourth groups of semiconductor chips 500 and 600 in the second direction (X direction). The third and fourth groups of semiconductor chips 500 and 600 may be between the first and second groups of semiconductor chips 300 and 400 and the second buffer chip 200b in the second direction (X direction). The second group of semiconductor chips 400 may be stacked on the first group of semiconductor chips 300, and the fourth group of semiconductor chips 600 may be stacked on the third group of semiconductor chips 500. The first group of semiconductor chips 300 and the third group of semiconductor chips 500 may be arranged to be spaced apart from each other on an upper surface 112 of the package substrate 110.

In example embodiments, first, second, third, and fourth lower semiconductor chips 300a, 300b, 300c, and 300d of the first group of semiconductor chips 300 may be sequentially offset in the second direction (X direction) on the package substrate 110. First, second, third, and fourth upper semiconductor chips 400a, 400b, 400c, and 400d of the second group of semiconductor chips 400 may be sequentially offset in the second direction (X direction).

When viewed from plan view, the first upper semiconductor chip 400a of the second group of semiconductor chips 400 may overlap with the first lower semiconductor chip 300a of the first group of semiconductor chips 300, the second upper semiconductor chip 400b may overlap with the second lower semiconductor chip 300b, the third upper semiconductor chip 400c may overlap with the third lower semiconductor chip 300c, and the fourth upper semiconductor chip 400d may overlap with the fourth lower semiconductor chip 300d. For example, the first lower semiconductor chip 300a and the first upper semiconductor chip 400a may be aligned in the second direction (X direction), the second lower semiconductor chip 300b and the second upper semiconductor chip 400b may be aligned in the second direction (X direction), the third lower semiconductor chip 300c and the third upper semiconductor chip 400c may be aligned in the second direction (X direction), and the fourth lower semiconductor chip 300d and the fourth upper semiconductor chip 400d may be aligned in the second direction (X direction).

In example embodiments, first, second, third, and fourth lower semiconductor chips 500a, 500b, 500c, and 500d of the third group of semiconductor chips 500 may be sequentially offset in the second direction (X direction) on the package substrate 110. First, second, third, and fourth upper semiconductor chips 600a, 600b, 600c, and 600d of the fourth group of semiconductor chips 600 may be sequentially offset in the second direction (X direction). In some embodiments, the first, second, third, and fourth lower semiconductor chips 500a, 500b, 500c, and 500d of the third group of semiconductor chips 500 may sequentially offset in the opposite direction to the direction in which the first, second, third, and fourth lower semiconductor chips 300a, 300b, 300c, and 300d of the first group of semiconductor chips 300 are sequentially offset. For example, in a cross-sectional view, the first group of semiconductor chips 300 and the third group of semiconductor chips 500 may form a symmetrical shape (in the second direction (X direction)). In some embodiments, the first, second, third, and fourth upper semiconductor chips 600a, 600b, 600c, and 600d of the fourth group of semiconductor chips 600 may sequentially offset in the opposite direction to the direction in which the first, second, third, and fourth upper semiconductor chips 400a, 400b, 400c, and 400d of the second group of semiconductor chips 400 are sequentially offset. For example, in a cross-sectional view, the second group of semiconductor chips 400 and the fourth group of semiconductor chips 600 may form a symmetrical shape (in the second direction (X direction)).

When viewed from plan view, the first upper semiconductor chip 600a of the fourth group of semiconductor chips 600 may overlap with the first lower semiconductor chip 500a of the third group of semiconductor chips 500, the second upper semiconductor chip 600b may overlap with the second lower semiconductor chip 500b, the third upper semiconductor chip 600c may overlap with the third lower semiconductor chip 500c, and the fourth upper semiconductor chip 600d may overlap with the fourth lower semiconductor chip 500d. For example, the first lower semiconductor chip 500a and the first upper semiconductor chip 600a may be aligned in the second direction (X direction), the second lower semiconductor chip 500b and the second upper semiconductor chip 600b may be aligned in the second direction (X direction), the third lower semiconductor chip 500c and the third upper semiconductor chip 600c may be aligned in the second direction (X direction), and the fourth lower semiconductor chip 500d and the fourth upper semiconductor chip 600d may be aligned in the second direction (X direction).

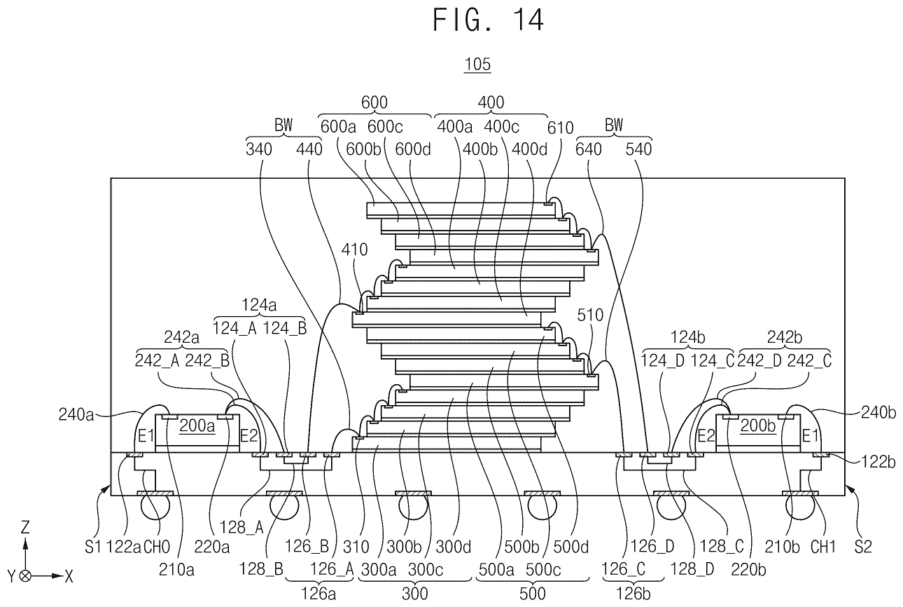

FIG. 14 is a cross-sectional view illustrating a semiconductor package in accordance with example embodiments. The semiconductor package (the semiconductor package 105) may be substantially the same as the semiconductor package (the semiconductor package 103) described with reference to FIG. 12 except for arrangements of first to fourth groups of semiconductor chips. Thus, same reference numerals may be used to refer to the same or like elements unless clearly described otherwise and any further repetitive explanation concerning the above elements may be omitted.

Referring to FIG. 14, a semiconductor package 105 may include a package substrate 110, a first buffer chip 200a, a second buffer chip 200b, a first group of semiconductor chips 300 (G1), and a fourth group of semiconductor chips 600 (G4). The semiconductor package 105 may be (electrically) connected to the host 20 by first and second external channels CH0 and CH1.

In example embodiments, the first buffer chip 200a may be arranged adjacent to a first side portion S1 of the package substrate 110. The second buffer chip 200b may be arranged adjacent to a second side portion S2 (opposite to the first side portion S1 in the second direction (X direction)) of the package substrate 110. The first, second, third, and fourth groups of semiconductor chips 300, 400, 500, and 600 may be on a middle region of the package substrate 110 (e.g., between the first and second buffer chips 200a and 200b in the second direction (X direction)).

In example embodiments, the third group of semiconductor chips 500 may be stacked on the first group of semiconductor chips 300, the second group of semiconductor chips 400 may be stacked on the third group of semiconductor chips 500, and the fourth group of semiconductor chips 600 may be stacked on the second group of semiconductor chips 400.

First, second, third, and fourth lower semiconductor chips 300a, 300b, 300c, and 300d of the first group of semiconductor chips 300 may be sequentially offset in the second direction (X direction) on the package substrate 110. First, second, third and fourth lower semiconductor chips 500a, 500b, 500c, and 500d of the third group of semiconductor chips 500 may be sequentially offset in the second direction (X direction) on the uppermost semiconductor chip (e.g., the fourth lower semiconductor chip 300d) of the first group of semiconductor chips 300. In some embodiments, the first, second, third, and fourth lower semiconductor chips 500a, 500b, 500c, and 500d of the third group of semiconductor chips 500 may be sequentially offset in a direction opposite to the direction in which the first, second, third, and fourth lower semiconductor chips 300a, 300b, 300c, and 300d of the first group of semiconductor chips 300 are sequentially offset. First, second, third, and fourth upper semiconductor chips 400a, 400b, 400c, and 400d of the second group of semiconductor chips 400 may be sequentially offset in the second direction (X direction) on the uppermost semiconductor chip (e.g., the fourth lower semiconductor chip 500d) of the third group of semiconductor chips 500. First, second, third, and fourth upper semiconductor chips 600a, 600b, 600c, and 600d of the fourth group of semiconductor chips 600 may be sequentially offset in the second direction (X direction) on the uppermost semiconductor chip (e.g., the fourth upper semiconductor chip 400d) of the second group of semiconductor chips 400. In some embodiments, the first, second, third, and fourth upper semiconductor chips 400a, 400b, 400c, and 400d of the second group of semiconductor chips 400 may be sequentially offset in a direction opposite to the direction in which the first, second, third, and fourth lower semiconductor chips 500a, 500b, 500c, and 500d of the third group of semiconductor chips 500 are sequentially offset. In some embodiments, the first, second, third, and fourth upper semiconductor chips 600a, 600b, 600c, and 600d of the fourth group of semiconductor chips 600 may be sequentially offset in a direction opposite to the direction in which the first, second, third, and fourth upper semiconductor chips 400a, 400b, 400c, and 400d of the second group of semiconductor chips 400 are sequentially offset. For example, the first, second, third, and fourth lower semiconductor chips 300a, 300b, 300c, and 300d of the first group of semiconductor chips 300 and the first, second, third, and fourth upper semiconductor chips 400a, 400b, 400c, and 400d of the second group of semiconductor chips 400 may be offset in the same direction. For example, the first, second, third, and fourth lower semiconductor chips 500a, 500b, 500c, and 500d of the third group of semiconductor chips 500 and the first, second, third, and fourth upper semiconductor chips 600a, 600b, 600c, and 600d of the fourth group of semiconductor chips 600 may be offset in the same direction.

When viewed from plan view, the first upper semiconductor chip 400a of the second group of semiconductor chips 400 may overlap with the first lower semiconductor chip 300a of the first group of semiconductor chips 300, the second upper semiconductor chip 400b may overlap with the second lower semiconductor chip 300b, the third upper semiconductor chip 400c may overlap with the third lower semiconductor chip 300c, and the fourth upper semiconductor chip 400d may overlap with the fourth lower semiconductor chip 300d. For example, the first lower semiconductor chip 300a and the first upper semiconductor chip 400a may be aligned in the second direction (X direction), the second lower semiconductor chip 300b and the second upper semiconductor chip 400b may be aligned in the second direction (X direction), the third lower semiconductor chip 300c and the third upper semiconductor chip 400c may be aligned in the second direction (X direction), and the fourth lower semiconductor chip 300d and the fourth upper semiconductor chip 400d may be aligned in the second direction (X direction).

When viewed from plan view, the first upper semiconductor chip 600a of the second group of semiconductor chips 600 may overlap with the first lower semiconductor chip 500a of the third group of semiconductor chips 500, the second upper semiconductor chip 600b may overlap with the second lower semiconductor chip 500b, the third upper semiconductor chip 600c may overlap with the third lower semiconductor chip 500c, and the fourth upper semiconductor chip 600d may overlap with the fourth lower semiconductor chip 500d. For example, the first lower semiconductor chip 500a and the first upper semiconductor chip 600a may be aligned in the second direction (X direction), the second lower semiconductor chip 500b and the second upper semiconductor chip 600b may be aligned in the second direction (X direction), the third lower semiconductor chip 500c and the third upper semiconductor chip 600c may be aligned in the second direction (X direction), and the fourth lower semiconductor chip 500d and the fourth upper semiconductor chip 600d may be aligned in the second direction (X direction).

In example embodiments, the first group of semiconductor chips 300 and the second group of semiconductor chips 400 may be (electrically) connected to the package substrate 110 by second bonding wires BW as conductive connection members. The second bonding wires BW may include first channel wires 340 and second channel wires 440. The first channel wires 340 may (electrically) connect chip pads 310 of the first group of semiconductor chips 300 to first channel memory-side pads 126_A of the package substrate 110. The second channel wires 440 may (electrically) connect chip pads 410 of the second group of semiconductor chips 400 to second channel memory-side pads 126_B of the package substrate 110.

In example embodiments, the third group of semiconductor chips 500 and the fourth group of semiconductor chips 600 may be (electrically) connected to the package substrate 110 by the second bonding wires BW as conductive connection members. The second bonding wires BW may include third channel wires 540 and fourth channel wires 640. The third channel wires 540 may (electrically) connect chip pads 510 of the third group of semiconductor chips 500 to third channel memory-side pads 126_C of the package substrate 110. The fourth channel wires 640 may (electrically) connect chip pads 610 of the fourth group of semiconductor chips 600 to fourth channel memory-side pads 126_D of the package substrate 110.

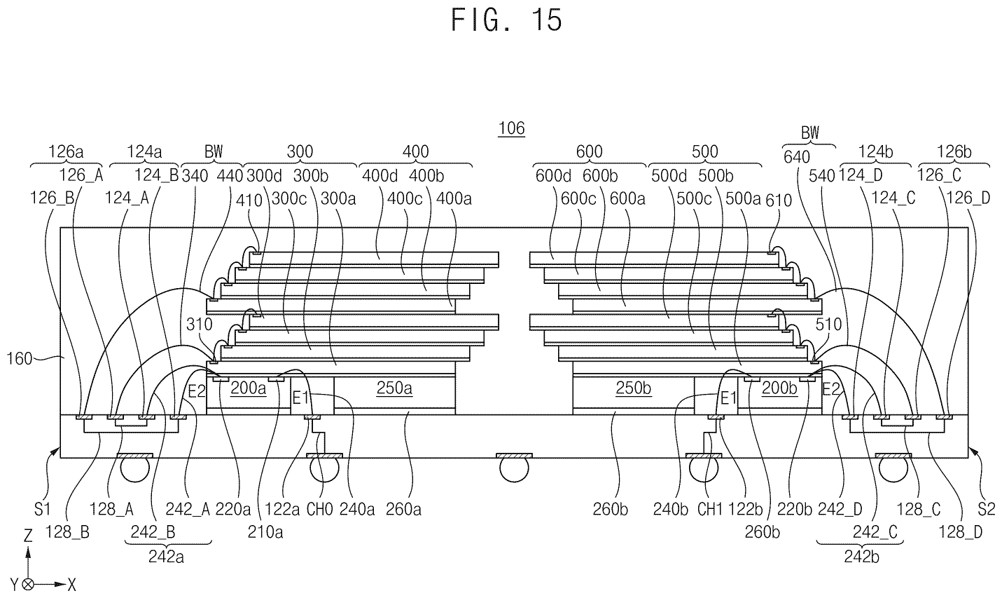

FIG. 15 is a cross-sectional view illustrating a semiconductor package in accordance with example embodiments. The semiconductor package (the semiconductor package 106) may be substantially the same as the semiconductor package (the semiconductor package 103) described with reference to FIG. 12 except for arrangements of first and second buffer chips, arrangements of first to fourth groups of semiconductor chips, and additional first and second spacer chips. Thus, same reference numerals may be used to refer to the same or like elements unless clearly described otherwise and any further repetitive explanation concerning the above elements may be omitted.

Referring to FIG. 15, a semiconductor package 106 may include a package substrate 110, a first buffer chip 200a, a second buffer chip 200b, a first group of semiconductor chips 300 (G1), a second group of semiconductor chips 400 (G2), a third group of semiconductor chips 500 (G3), and a fourth group of semiconductor chips 600 (G4). The semiconductor package 106 may further include a first spacer chip 250a and a second spacer chip 250b.

In example embodiments, the first buffer chip 200a may be arranged on an upper surface 112 of the package substrate 110 to be adjacent to a first side portion S1 of the package substrate 110, and the first spacer chip 250a may be arranged to be spaced apart from the first buffer chip 200a in the second direction (X direction) on the upper surface 112 of the package substrate 110. The second buffer chip 200b may be arranged on the upper surface 112 of the package substrate 110 to be adjacent to a second side portion S2 of the package substrate 110, and the second spacer chip 250b may be arranged on the upper surface 112 of the package substrate 110 to be spaced apart from the second buffer chip 200b in the second direction (X direction). In some embodiments, the first spacer chip 250a may be between the first side portion S1 of the package substrate 110 and the second spacer chip 250b in the second direction (X direction). The second spacer chip 250b may be between the second side portion S2 of the package substrate 110 and the first spacer chip 250a in the second direction (X direction). A second side E2 of the first buffer chip 200a may be arranged to be adjacent to the first side portion S1 of the package substrate 110. A second side E2 of the second buffer chip 200b may be arranged to be adjacent to the second side portion S2 of the package substrate 110.

For connection with a first external channel CH0, first external channel substrate pads 122a may be arranged to be spaced apart from each other in the first direction (Y direction) so as to be adjacent to a first side E1 of the first buffer chip 200a. The first side E1 of the first buffer chip 200a may be the opposite to the second side E2 of the first buffer chip 200a in the second direction (X direction). The first external channel substrate pads 122a may be arranged between the first buffer chip 200a and the first spacer chip 250a (in the second direction (X direction)). First buffer-side internal channel substrate pads 124a may be arranged to be spaced apart from each other in the first direction (Y direction) along the first side portion S1 of the package substrate 110. The first buffer-side internal channel substrate pads 124a may be arranged so as to be adjacent to the second side E2 of the first buffer chip 200a. For example, the first buffer-side internal channel substrate pads 124a may be between the first side portion S1 of the package substrate 110 and the second side E2 of the first buffer chip 200a in the second direction (X direction). The first buffer-side internal channel substrate pads 124a may be arranged to be spaced apart from each other in the first direction (Y direction). First memory-side internal channel substrate pads 126a may be arranged to be spaced apart from each other in the first direction (Y direction) to correspond to the first buffer-side internal channel substrate pads 124a, respectively. The first memory-side internal channel substrate pads 126a may be arranged adjacent to the first side portion S1 of the package substrate 110. For example, the first memory-side internal channel substrate pads 126a may be between the first side portion S1 of the package substrate 110 and the first buffer-side internal channel substrate pads 124a in the second direction (X direction). The first memory-side internal channel substrate pads 126a may be (electrically) connected to the first buffer-side internal channel substrate pads 124a, respectively, by substrate wiring (e.g., the first wiring 128_A and/or the second wiring 128_B).

For connection with a second external channel CH1, second external channel substrate pads 122b may be arranged to be spaced apart from each other in the first direction (Y direction) so as to be adjacent to a first side E1 of the second buffer chip 200b. The second external channel substrate pads 122b may be arranged between the second buffer chip 200b and the second spacer chip 250b (in the second direction (X direction)). Second buffer-side internal channel substrate pads 124b may be arranged to be spaced apart from each other in the first direction (Y direction) along the second side portion S2 of the package substrate 110. The second buffer-side internal channel substrate pads 124b may be arranged to be adjacent to the second side E2 of the second buffer chip 200b. The second buffer-side internal channel substrate pads 124b may be arranged to be spaced apart from each other in the first direction (Y direction). Second memory-side internal channel substrate pads 126b may be arranged to be spaced apart from each other in the first direction (Y direction) to correspond to the second buffer-side internal channel substrate pads 124b, respectively. The second memory-side internal channel substrate pads 126b may be arranged to be adjacent to the second side portion S2 of the package substrate 110. The second memory-side internal channel substrate pads 126b may be (electrically) connected to the second buffer-side internal channel substrate pads 124b, respectively, by the substrate wirings (e.g., the third wiring 128_C and/or the fourth wiring 128_D).

In example embodiments, the first group of semiconductor chips 300 may be stacked on the first buffer chip 200a and the first spacer chip 250a. The second group of semiconductor chips 400 may be stacked on the first group of semiconductor chips 300. The third group of semiconductor chips 500 may be stacked on the second buffer chip 200b and the second spacer chip 250b. The fourth group of semiconductor chips 600 may be stacked on the third group of semiconductor chips 500.

The first and second spacer chips 250a and 250b may be attached to the upper surface 112 of the package substrate 110 by adhesive films 260a and 260b (respectively). The first and second spacer chips 250a and 250b may include, for example, a silicon material. The first and second spacer chips 250a and 250b may be formed by cutting a silicon wafer using a sawing process using a blade.

In example embodiments, first, second, third, and fourth lower semiconductor chips 300a, 300b, 300c, and 300d of the first group of semiconductor chips 300 may be sequentially offset in the second direction (X direction) on the first buffer chip 200a and the first spacer chip 250a. First, second, third, and fourth upper semiconductor chips 400a, 400b, 400c, and 400d of the second group of semiconductor chips 400 may be sequentially offset in the second direction (X direction). The first, second, third, and fourth lower semiconductor chips 300a, 300b, 300c, and 300d of the first group of semiconductor chips 300 and the first, second, third, and fourth upper semiconductor chips 400a, 400b, 400c, and 400d of the second group of semiconductor chips 400 may be offset in the same direction.

When viewed from plan view, the first upper semiconductor chip 400a of the second group of semiconductor chips 400 may overlap with the first lower semiconductor chip 300a of the first group of semiconductor chips 300, the second upper semiconductor chip 400b may overlap with the second lower semiconductor chip 300b, the third upper semiconductor chip 400c may overlap with the third lower semiconductor chip 300c, and the fourth upper semiconductor chip 400d may overlap with the fourth lower semiconductor chip 300d. For example, the first lower semiconductor chip 300a and the first upper semiconductor chip 400a may be aligned in the second direction (X direction), the second lower semiconductor chip 300b and the second upper semiconductor chip 400b may be aligned in the second direction (X direction), the third lower semiconductor chip 300c and the third upper semiconductor chip 400c may be aligned in the second direction (X direction), and the fourth lower semiconductor chip 300d and the fourth upper semiconductor chip 400d may be aligned in the second direction (X direction).

In example embodiments, first, second, third, and fourth lower semiconductor chips 500a, 500b, 500c, and 500d of the third group of semiconductor chips 500 may be sequentially offset in the second direction (X direction) on the second buffer chip 200b and the second spacer chip 250b. In some embodiments, the first, second, third, and fourth lower semiconductor chips 500a, 500b, 500c, and 500d of the third group of semiconductor chips 500 may be sequentially offset in the direction opposite to the direction in which the first, second, third, and fourth lower semiconductor chips 300a, 300b, 300c, and 300d of the first group of semiconductor chips 300 are sequentially offset. For example, the first, second, third, and fourth lower semiconductor chips 500a, 500b, 500c, and 500d of the third group of semiconductor chips 500 and the first, second, third, and fourth lower semiconductor chips 300a, 300b, 300c, and 300d of the first group of semiconductor chips 300 may form a symmetrical shape in a cross-sectional view (in the second direction (X direction)). First, second, third and fourth upper semiconductor chips 600a, 600b, 600c, 600d of the fourth group of semiconductor chips 600 may be sequentially offset in the direction opposite to the second direction (X direction). The first, second, third, and fourth lower semiconductor chips 500a, 500b, 500c, and 500d of the third group of semiconductor chips 500 and the first, second, third, and fourth upper semiconductor chips 600a, 600b, 600c, and 600d of the fourth group of semiconductor chips 600 may be offset in the same direction. In some embodiments, the first, second, third, and fourth upper semiconductor chips 600a, 600b, 600c, and 600d of the fourth group of semiconductor chips 600 may be sequentially offset in the direction opposite to the direction in which the first, second, third, and fourth upper semiconductor chips 400a, 400b, 400c, and 400d of the second group of semiconductor chips 400 are sequentially offset. For example, the first, second, third, and fourth upper semiconductor chips 600a, 600b, 600c, and 600d of the fourth group of semiconductor chips 600 and the first, second, third, and fourth upper semiconductor chips 400a, 400b, 400c, and 400d of the second group of semiconductor chips 400 may form a symmetrical shape in a cross-sectional view (in the second direction (X direction)).

When viewed from plan view, the first upper semiconductor chip 600a of the fourth group of semiconductor chips 600 may overlap with the first lower semiconductor chip 500a of the third group of semiconductor chips 500, the second upper semiconductor chip 600b may overlap with the second lower semiconductor chip 500b, the third upper semiconductor chip 600c may overlap with the third lower semiconductor chip 500c, and the fourth upper semiconductor chip 600d may overlap with the fourth lower semiconductor chip 500d. For example, the first lower semiconductor chip 500a and the first upper semiconductor chip 600a may be aligned in the second direction (X direction), the second lower semiconductor chip 500b and the second upper semiconductor chip 600b may be aligned in the second direction (X direction), the third lower semiconductor chip 500c and the third upper semiconductor chip 600c may be aligned in the second direction (X direction), and the fourth lower semiconductor chip 500d and the fourth upper semiconductor chip 600d may be aligned in the second direction (X direction).

In example embodiments, the first group of semiconductor chips 300 and the second group of semiconductor chips 400 may be (electrically) connected to the package substrate 110 by second bonding wires BW as conductive connection members. The second bonding wires BW may include first channel wires 340 and second channel wires 440. The first channel wires 340 may (electrically) connect chip pads 310 of the first group of semiconductor chips 300 to first channel memory-side pads 126_A of the package substrate 110. The second channel wires 440 may (electrically) connect chip pads 410 of the second group of semiconductor chips 400 to second channel memory-side pads 126_B of the package substrate 110.

A first channel buffer pad 220_A, a first channel buffer-side pad 124_A, and the first channel memory-side pad 126_A may form (at least) a portion of a first internal channel A for transmitting data signals between the first buffer chip 200a and the first group of semiconductor chips 300. A second channel buffer pad 220_B, a second channel buffer-side pad 124_B, and the second channel memory-side pad 126_B may form (at least) a portion of a second internal channel B for transmitting data signals between the first buffer chip 200a and the second group of semiconductor chips 400.

In example embodiments, the third group of semiconductor chips 500 and the fourth group of semiconductor chips 600 may be (electrically) connected to the package substrate 110 by the second bonding wires BW as conductive connection members. The second bonding wires BW may include third channel wires 540 and fourth channel wires 640. The third channel wires 540 may (electrically) connect chip pads 510 of the third group of semiconductor chips 500 to third channel memory-side pads 126_C of the package substrate 110. The fourth channel wires 640 may (electrically) connect chip pads 610 of the fourth group of semiconductor chips 600 to fourth channel memory-side pads 126_D of the package substrate 110.

A third channel buffer pad 220_C, a third channel buffer-side pad 124_C, and the third channel memory-side pad 126_C may form (at least) a portion of a third internal channel C for transmitting data signals between the second buffer chip 200b and the third group of semiconductor chips 500. A fourth channel buffer pad 220_D, a fourth channel buffer-side pad 124_D, and the fourth channel memory-side pad 126_D may form (at least) a portion of a fourth internal channel D for transmitting data signals between the second buffer chip 200b and the fourth group of semiconductor chips 600.

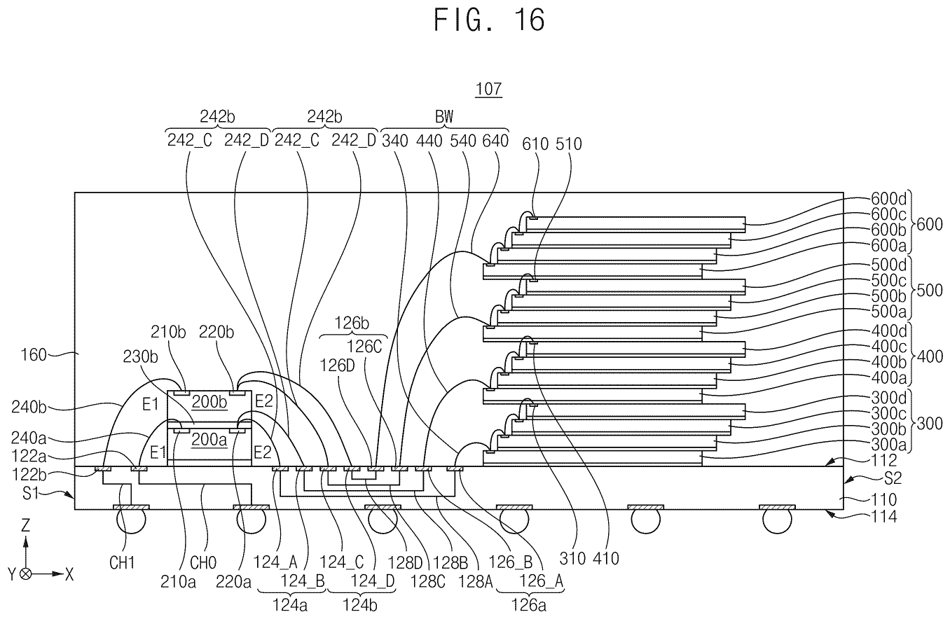

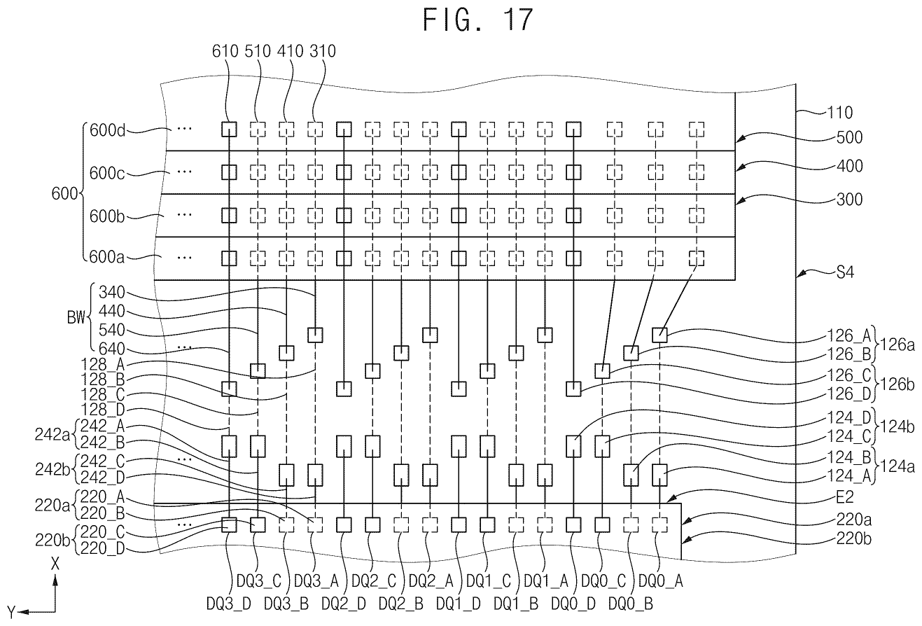

FIG. 16 is a cross-sectional view illustrating a semiconductor package in accordance with example embodiments. FIG. 17 is a plan view illustrating a portion of the semiconductor package in FIG. 16. The semiconductor package (the semiconductor package 107) may be substantially the same as the semiconductor package (the semiconductor package 103) described with reference to FIG. 12 except for arrangements of first and second buffer chips and arrangements of first to fourth groups of semiconductor chips. Thus, same reference numerals may be used to refer to the same or like elements unless clearly described otherwise and any further repetitive explanation concerning the above elements may be omitted.

Referring to FIGS. 16 and 17, a semiconductor package 107 may include a package substrate 110, a first buffer chip 200a, a second buffer chip 200b, a first group of semiconductor chips 300 (G1), a second group of semiconductor chips 400 (G2), a third group of semiconductor chips 500 (G3), and a fourth group of semiconductor chips 600 (G4).

In example embodiments, the first buffer chip 200a may be arranged on an upper surface 112 of the package substrate 110 to be adjacent to a first side portion S1 of the package substrate 110, and the second buffer chip 200b may be stacked on the first buffer chip 200a. The second buffer chip 200b may be attached to the first buffer chip 200a by an adhesive film 230b. A first side E1 of the first buffer chip 200a may be arranged to be adjacent to a first side portion S1 of the package substrate 110. A first side E1 of the second buffer chip 200b may be arranged to be adjacent to the first side portion S1 of the package substrate 110.

For connection with the first external channel CH0, first external channel substrate pads 122a may be arranged to be spaced apart from each other in the first direction (Y direction) along the first side portion S1 of the package substrate 110. The first external channel substrate pads 122a may be arranged to be adjacent to the first side E1 of the first buffer chip 200a. The first external channel substrate pads 122a may be between the first side portion S1 of the package substrate 110 and the first side E1 of the first buffer chip 200a in the second direction (X direction). First buffer-side internal channel substrate pads 124a may be arranged to be adjacent to a second side E2 of the first buffer chip 200a opposite to the first side E1 (in the second direction (X direction)). The first buffer-side internal channel substrate pads 124a may be arranged to be spaced apart from each other in the first direction (Y direction). First memory-side internal channel substrate pads 126a may be arranged to be spaced apart from each other in the first direction (Y direction) so as to respectively correspond to the first buffer-side internal channel substrate pads 124a. The first memory-side internal channel substrate pads 126a may be (electrically) connected to the first buffer-side internal channel substrate pads 124a by substrate wirings (e.g., the first internal wiring 128_A and the second internal wiring 128_B), respectively.

For connection with a second external channel CH1, second external channel substrate pads 122b may be arranged to be spaced apart from each other in the first direction (Y direction) along the first side portion S1 of the package substrate 110. The second external channel substrate pads 122b may be arranged adjacent to the first side E1 of the second buffer chip 200b. For example, the second external channel substrate pads 122b may be between the first side portion S1 of the package substrate 110 and the first side E1 of the second buffer chip 200b in the second direction (X direction). The first external channel substrate pads 122a may be arranged closer to the first side E1 of the first buffer chip 200a than the second external channel substrate pads 122b. For example, the first external channel substrate pads 122a may be between (the first side E1 of) the first buffer chip 200a and the second external channel substrate pads 122b in the second direction (X direction). Second buffer-side internal channel substrate pads 124b may be arranged adjacent to a second side E2 of the second buffer chip 200b opposite the first side E1 (in the second direction (X direction)). The second buffer-side internal channel substrate pads 124b may be arranged to be spaced apart from each other in the first direction (Y direction). Second memory-side internal channel substrate pads 126b may be arranged to be spaced apart from each other in the first direction (Y direction) so as to respectively correspond to the second buffer-side internal channel substrate pads 124b. The second memory-side internal channel substrate pads 126b may be (electrically) connected to the second buffer-side internal channel substrate pads 124b, respectively, by the substrate wirings (e.g., the third internal wiring 128_C and the fourth internal wiring 128_D).

Buffer chip pads of the first buffer chip 200a may include first external channel buffer pads 210a and first internal channel buffer pads 220a. The first external channel buffer pads 210a may be arranged to be spaced apart from each other along the first side E1 of the first buffer chip 200a (in the first direction (Y direction)) on an upper surface of the first buffer chip 200a. The first internal channel buffer pads 220a may be arranged to be spaced apart from each other along the second side E2 of the first buffer chip 200a (in the first direction (Y direction)) on the upper surface of the first buffer chip 200a.

The first internal channel buffer pads 220a may include first channel buffer pads 220_A and second channel buffer pads 220_B that are alternately arranged in the first direction (Y direction). The first channel buffer pads 220_A may be data signal pads for transmitting a data signal through a first internal channel A. The second channel buffer pads 220_B may be data signal pads for transmitting a data signal through a second internal channel B. When there are eight signals (DQ0_A, DQ1_A, . . . , and DQ7_A) for the first internal channel A and eight signals (DQ0_B, DQ1_B, . . . , DQ7_B) for the second internal channel B, the sixteen (16) (e.g., eight pairs of) first and second channel buffer pads 220A and 220B may be arranged alternately in the first direction (Y direction) as DQ0_A, DQ0_B, DQ1_A, DQ1_B, DQ2_A, DQ2_B, DQ3_A, DQ3_B, DQ4_A, DQ4_B, DQ5_A, DQ5_B, DQ6_A, DQ6_B, DQ7_A, and DQ7_B. For example, a first one of the first channel buffer pads 220_A for DQ0_A, a first one of the second channel buffer pads 220_B for DQ0_B, a second one of the first channel buffer pads 220_A for DQ1_A, a second one of the second channel buffer pads 220_B for DQ1_B, a third one of the first channel buffer pads 220_A for DQ2_A, a third one of the second channel buffer pads 220_B for DQ2_B, a fourth one of the first channel buffer pads 220_A for DQ3_A, a fourth one of the second channel buffer pads 220_B for DQ3_B, a fifth one of the first channel buffer pads 220_A for DQ4_A, a fifth one of the second channel buffer pads 220_B for DQ4_B, a sixth one of the first channel buffer pads 220_A for DQ5_A, a sixth one of the second channel buffer pads 220_B for DQ5_B, a seventh one of the first channel buffer pads 220_A for DQ6_A, a seventh one of the second channel buffer pads 220_B for DQ6_B, an eighth one of the first channel buffer pads 220_A for DQ7_A, and an eighth one of the second channel buffer pads 220_B for DQ7_B may be sequentially arranged in the first direction (Y direction).

Buffer chip pads of the second buffer chip 200b may include second external channel buffer pads 210b and second internal channel buffer pads 220b. The second external channel buffer pads 210b may be arranged to be spaced apart from each other along the first side E1 of the second buffer chip 200b (in the first direction (Y direction)) on the upper surface of the second buffer chip 200b. The second internal channel buffer pads 220b may be arranged to be spaced apart from each other along the second side E2 of the second buffer chip 200b (in the first direction (Y direction)) on the upper surface of the second buffer chip 200b.

The second internal channel buffer pads 220b may include third channel buffer pads 220_C and fourth channel buffer pads 220_D that are alternately arranged in the first direction (Y direction). The third channel buffer pads 220_C may be data signal pads for transmitting a data signal through a third internal channel C. The fourth channel buffer pads 220_D may be signal pads for transmitting a data signal through a fourth internal channel D. When there are eight signals (DQ0_C, DQ1_C, . . . , and DQ7_C) for the third internal channel C and eight signals (DQ0_D, DQ1_D, . . . , and DQ7_D) for the fourth internal channel D, the sixteen (16) (e.g., eight pairs of) third and fourth channel buffer pads 220_C and 220_D may be arranged alternately in the first direction (Y direction) as DQ0_C, DQ0_D, DQ1_C, DQ1_D, DQ2_C, DQ2_D, DQ3_C, DQ3_D, DQ4_C, DQ4_D, DQ5_C, DQ5_D, DQ6_C, DQ6_D, DQ7_C, DQ7_D. For example, a first one of the third channel buffer pads 220_C for DQ0_C, a first one of the fourth channel buffer pads 220_D for DQ0_D, a second one of the third channel buffer pads 220_C for DQ1_C, a second one of the fourth channel buffer pads 220_D for DQ1_D, a third one of the third channel buffer pads 220_C for DQ2_C, a third one of the fourth channel buffer pads 220_D for DQ2_D, a fourth one of the third channel buffer pads 220_C for DQ3_C, a fourth one of the fourth channel buffer pads 220_D for DQ3_D, a fifth one of the third channel buffer pads 220_C for DQ4_C, a fifth one of the fourth channel buffer pads 220_D for DQ4_D, a sixth one of the third channel buffer pads 220_C for DQ5_C, a sixth one of the fourth channel buffer pads 220_D for DQ5_D, a seventh one of the third channel buffer pads 220_C for DQ6_C, a seventh one of the fourth channel buffer pads 220_D for DQ6_D, an eighth one of the third channel buffer pads 220_C for DQ7_C, and an eighth one of the fourth channel buffer pads 220_D for DQ7_D may be sequentially arranged in the first direction (Y direction).

As illustrated in FIG. 17, the first buffer-side internal channel substrate pads 124a may be arranged adjacent to the second side E2 of the first buffer chip 200a. The second buffer-side internal channel substrate pads 124b may be arranged adjacent to the second side E2 of the second buffer chip 200b. In some embodiments, the second side E2 of the first buffer chip 200a and the second side E2 of the second buffer chip 200b may be aligned in the third direction (Z direction). For example, the second buffer-side internal channel substrate pads 124b may be arranged adjacent to the second side E2 of the first buffer chip 200a. The first buffer-side internal channel substrate pads 124a and the second buffer-side internal channel substrate pads 124b may be arranged to be spaced apart from each other in the first direction (Y direction). The first buffer-side internal channel substrate pads 124a may be arranged closer to the second side E2 of the first buffer chip 200a than the second buffer-side internal channel substrate pads 124b.

The first memory-side internal channel substrate pads 126a may be arranged to be spaced apart from each other in the first direction (Y direction) so as to correspond to the first buffer-side internal channel substrate pads 124a, respectively. The first memory-side internal channel substrate pads 126a may be (electrically) connected to the first buffer-side internal channel substrate pads 124a, respectively, by the substrate wiring (e.g., the first internal wiring 128_A and the second internal wiring 128_B). The second memory-side internal channel substrate pads 126b may be arranged to be spaced apart from each other in the first direction (Y direction) so as to correspond to the second buffer-side internal channel substrate pads 124b, respectively. The second memory-side internal channel substrate pads 126b may be (electrically) connected to the second buffer-side internal channel substrate pads 124b, respectively, by the substrate wiring (e.g., the third internal wiring 128_C and the fourth internal wiring 128_D). The first memory-side internal channel substrate pads 126a may be arranged closer to the lowermost semiconductor chip (e.g., the first lower semiconductor chip 300a) of the first group of semiconductor chips 300 than the second memory-side internal channel substrate pads 126b.

The first buffer-side internal channel substrate pads 124a may include first channel buffer-side pads 124_A and second channel buffer-side pads 124_B. The second buffer-side internal channel substrate pads 124b may include third channel buffer-side pads 124_C and fourth channel buffer-side pads 124_D. The first, second, third, and fourth channel buffer-side pads 124_A, 124_B, 124_C, and 124_D may be arranged sequentially in the first direction (Y direction).

The first memory-side internal channel substrate pads 126a may include first channel memory-side pads 126_A and second channel memory-side pads 126_B. The second memory-side internal channel substrate pads 126b may include third channel memory-side pads 126_C and fourth channel memory-side pads 126_D. The first, second, third, and fourth channel memory-side pads 126_A, 126_B, 126_C, and 126_D may be arranged sequentially in the first direction (Y direction).

The first channel buffer pads 220_A of the first buffer chip 200a may be (electrically) connected to the first channel buffer-side pads 124_A of the package substrate 110 by first channel buffer-side wires 242_A. The second channel buffer pads 220_B of the first buffer chip 200a may be (electrically) connected to the second channel buffer-side pads 124_B of the package substrate 110 by second channel buffer-side wires 242_B. The first channel buffer-side pads 124_A and the second channel buffer-side pads 124_B may be (electrically) connected to the first channel memory-side pads 126_A and the second channel memory-side pads 126_B by the substrate wirings (e.g., the first internal wiring 128_A and the second internal wiring 128_B), respectively.

The third channel buffer pads 220_C of the second buffer chip 200b may be (electrically) connected to the third channel buffer-side pads 124_C of the package substrate 110 by third channel buffer-side wires 242_C. The fourth channel buffer pads 220_D of the second buffer chip 200b may be (electrically) connected to the fourth channel buffer-side pads 124_D of the package substrate 110 by fourth channel buffer-side wires 242_D. The third channel buffer-side pads 124_C and the fourth channel buffer-side pads 124_D may be (electrically) connected to the third channel memory-side pads 126_C and the fourth channel memory-side pads 126_D by the substrate wirings (e.g., the third internal wiring 128_C and the fourth internal wiring 128_D), respectively.

Since the first and second channel buffer pads 220_A and 220_B and the third and fourth channel buffer pads 220_C and 220_D are arranged sequentially in the first direction (Y direction), the first, second, third, and fourth channel buffer-side pads 124_A, 124_B, 124_C, and 124_D and the first, second, third, and fourth channel memory-side pads 126_A, 126_B, 126_C, and 126_D may also be arranged sequentially in the first direction (Y direction). Accordingly, the internal wirings (e.g., the first, second, third, and fourth internal wirings 128_A, 128_B, 128_C, and 128_D) (electrically) connecting the first, second, third, and fourth channel buffer-side pads 124_A, 124_B, 124_C, and 124_D and the first, second, third, and fourth channel memory-side pads 126_A, 126_B, 126_C, and 126D may be arranged on the same circuit layer.

In example embodiments, the first group of semiconductor chips 300 of the may be stacked on the upper surface 112 of the package substrate 110, the second group of semiconductor chips 400 may be stacked on the first group of semiconductor chips 300, the third group of semiconductor chips 500 may be stacked on the second group of semiconductor chips 400, and the fourth group of semiconductor chips 600 may be stacked on the third group of semiconductor chips 500.

First, second, third, and fourth lower semiconductor chips 300a, 300b, 300c, and 300d of the first group of semiconductor chips 300 may be sequentially offset in the second direction (X direction) on the package substrate 110. First, second, third, and fourth upper semiconductor chips 400a, 400b, 400c, and 400d of the second group of semiconductor chips 400 may be sequentially offset in the second direction (X direction). First, second, third, and fourth lower semiconductor chips 500a, 500b, 500c, and 500d of the third group of semiconductor chips 500 may be sequentially offset in the second direction (X direction) on the uppermost semiconductor chip (e.g., the fourth upper semiconductor chip 400d) of the second group of semiconductor chips 400. First, second, third, and fourth upper semiconductor chips 600a, 600b, 600c, and 600d of the fourth group of semiconductor chips 600 may be sequentially offset in the second direction (X direction). For example, the first, second, third, and fourth lower semiconductor chips 300a, 300b, 300c, and 300d of the first group of semiconductor chips 300, the first, second, third, and fourth upper semiconductor chips 400a, 400b, 400c, and 400d of the second group of semiconductor chips 400, the first, second, third, and fourth lower semiconductor chips 500a, 500b, 500c, and 500d of the third group of semiconductor chips 500, and the first, second, third, and fourth upper semiconductor chips 600a, 600b, 600c, and 600d of the fourth group of semiconductor chips 600 may be offset in the same direction (e.g., the second direction (X direction)).

When viewed from plan view, the first upper semiconductor chip 400a of the second group of semiconductor chips 400 may overlap with the first lower semiconductor chip 300a of the first group of semiconductor chips 300, the second upper semiconductor chip 400b may overlap with the second lower semiconductor chip 300b, the third upper semiconductor chip 400c may overlap with the third lower semiconductor chip 300c, and the fourth upper semiconductor chip 400d may overlap with the fourth lower semiconductor chip 300d.

Similarly, the first, second, third, and fourth lower semiconductor chips 500a, 500b, 500c, and 500d of the third group of semiconductor chips 500 may overlap the first, second, third, and fourth upper semiconductor chips 400a, 400b, 400c, and 400d of the second group of semiconductor chips 400, respectively, and the first, second, third, and fourth upper semiconductor chips 600a, 600b, 600c, and 600d of the fourth group of semiconductor chips 600 may overlap the first, second, third, and fourth lower semiconductor chips 500a, 500b, 500c, and 500d of the third group of semiconductor chips 500, respectively. For example, side surfaces of the first lower semiconductor chip 300a of the first group of semiconductor chips 300, the first upper semiconductor chip 400a of the second group of semiconductor chips 400, the first lower semiconductor chip 500a of the third group of semiconductor chips 500, and the first upper semiconductor chip 600a of the fourth group of semiconductor chips 600 may be aligned with each other in the third direction (Z direction). For example, side surfaces of the second lower semiconductor chip 300b of the first group of semiconductor chips 300, the second upper semiconductor chip 400b of the second group of semiconductor chips 400, the second lower semiconductor chip 500b of the third group of semiconductor chips 500, and the second upper semiconductor chip 600b of the fourth group of semiconductor chips 600 may be aligned with each other in the third direction (Z direction). For example, side surfaces of the third lower semiconductor chip 300c of the first group of semiconductor chips 300, the third upper semiconductor chip 400c of the second group of semiconductor chips 400, the third lower semiconductor chip 500c of the third group of semiconductor chips 500, and the third upper semiconductor chip 600c of the fourth group of semiconductor chips 600 may be aligned with each other in the third direction (Z direction). For example, side surfaces of the fourth lower semiconductor chip 300d of the first group of semiconductor chips 300, the fourth upper semiconductor chip 400d of the second group of semiconductor chips 400, the fourth lower semiconductor chip 500d of the third group of semiconductor chips 500, and the fourth upper semiconductor chip 600d of the fourth group of semiconductor chips 600 may be aligned with each other in the third direction (Z direction).

In example embodiments, the first group of semiconductor chips 300, the second group of semiconductor chips 400, the third group of semiconductor chips 500, and the fourth group of semiconductor chips 600 may be (electrically) connected to the package substrate 110 by second bonding wires BW as conductive connection members. The second bonding wires BW may include first channel wires 340, second channel wires 440, third channel wires 540, and fourth channel wires 640. The first channel wires 340 may (electrically) connect chip pads 310 of the first group of semiconductor chips 300 to the first channel memory-side pads 126_A of the package substrate 110. The second channel wires 440 may (electrically) connect chip pads 410 of the second group of semiconductor chips 400 to the second channel memory-side pads 126_B of the package substrate 110. The third channel wires 540 may (electrically) connect chip pads 510 of the third group of semiconductor chips 500 to the third channel memory-side pads 126_C of the package substrate 110. The fourth channel wires 640 may (electrically) connect chip pads 610 of the fourth group of semiconductor chips 600 to the fourth channel memory-side pads 126_D of the package substrate 110.

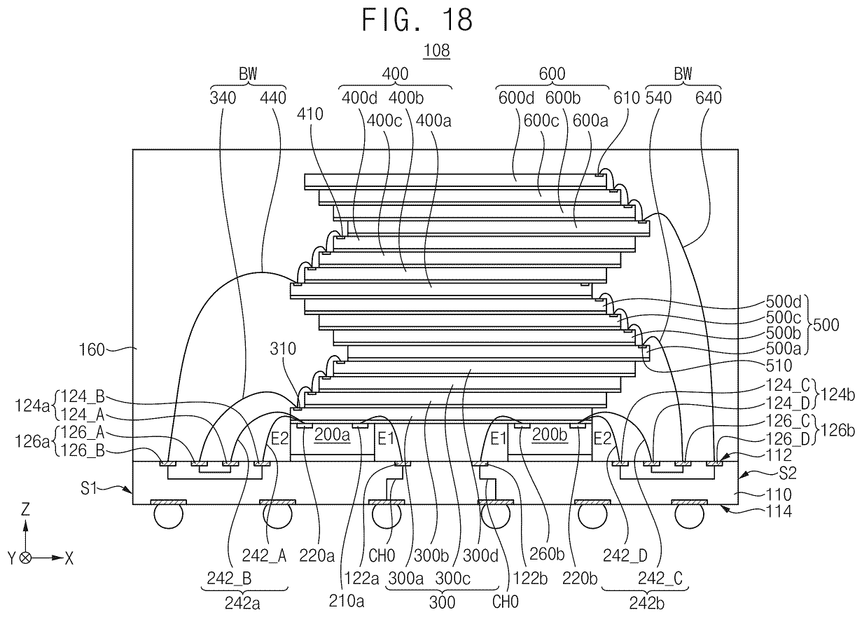

FIG. 18 is a cross-sectional view illustrating a semiconductor package in accordance with example embodiments. The semiconductor package (the semiconductor package 108) may be substantially the same as the semiconductor package (the semiconductor package 105) described with reference to FIG. 14 except for arrangements of first and second buffer chips and arrangements of first to fourth groups of semiconductor chips. Thus, same reference numerals may be used to refer to the same or like elements unless clearly described otherwise and any further repetitive explanation concerning the above elements may be omitted.

Referring to FIG. 18, a semiconductor package 108 may include a package substrate 110, a first buffer chip 200a, a second buffer chip 200b, a first group of semiconductor chips 300 (G1), a second group of semiconductor chips 400 (G2), a third group of semiconductor chips 500 (G3), and a fourth group of semiconductor chips 600 (G4).

In example embodiments, the first buffer chip 200a may be arranged on an upper surface 112 of the package substrate 110 to be adjacent to a first side portion S1 of the package substrate 110, and the second buffer chip 200b may be arranged on the upper surface 112 of the package substrate 110 to be adjacent to a second side portion S2 of the package substrate 110. The first buffer chip 200a and the second buffer chip 200b may be arranged to be spaced apart from each other (in the second direction (X direction)). A second side E2 of the first buffer chip 200a may be arranged to be adjacent to the first side portion S1 of the package substrate 110, and a second side E2 of the second buffer chip 200b may be arranged to be adjacent to the second side portion S2 of the package substrate 110.

For connection with a first external channel CH0, first external channel substrate pads 122a may be arranged to be spaced apart from each other in a first direction (Y direction) so as to be adjacent to the first side E1 of the first buffer chip 200a. First buffer-side internal channel substrate pads 124a may be arranged to be spaced apart from each other in the first direction (Y direction) along the first side portion S1 of the package substrate 110. The first buffer-side internal channel substrate pads 124a may be arranged to be adjacent to the second side E2 of the first buffer chip 200a (opposite to the first side E1 of the first buffer chip 200a in the second direction (X direction)). For example, the first buffer-side internal channel substrate pads 124a may be between the first side portion S1 of the package substrate 110 and the second side E2 of the first buffer chip 200a in the second direction (X direction). The first buffer-side internal channel substrate pads 124a may be arranged to be spaced apart from each other in the first direction (Y direction). First memory-side internal channel substrate pads 126a may be arranged to be spaced apart from each other in the first direction (Y direction) so as to respectively correspond to the first buffer-side internal channel substrate pads 124a. The first memory-side internal channel substrate pads 126a may be arranged to be adjacent to the first side portion S1 of the package substrate 110. For example, the first memory-side internal channel substrate pads 126a may be between the first side portion S1 of the package substrate 110 and the first buffer-side internal channel substrate pads 124a in the second direction (X direction). The first memory-side internal channel substrate pads 126a may be (electrically) connected to the first buffer-side internal channel substrate pads 124a, respectively by substrate wirings.

For connection with a second external channel CH1, second external channel substrate pads 122b may be arranged to be spaced apart from each other in the first direction (Y direction) so as to be adjacent to the first side E1 of the second buffer chip 200b. Second buffer-side internal channel substrate pads 124b may be arranged to be spaced apart from each other in the first direction (Y direction) along the second side portion S2 of the package substrate 110. The second buffer-side internal channel substrate pads 124b may be arranged to be spaced apart from each other in the first direction (Y direction). Second memory-side internal channel substrate pads 126b may be arranged to be spaced apart from each other in the first direction (Y direction) so as to correspond to the second buffer-side internal channel substrate pads 124b, respectively. The second memory-side internal channel substrate pads 126b may be arranged to be adjacent to the second side portion S2 of the package substrate 110. For example, the second memory-side internal channel substrate pads 126b between the second side portion S2 of the package substrate 110 and the second buffer-side internal channel substrate pads 124b in the second direction (X direction). The second memory-side internal channel substrate pads 126b may be (electrically) connected to the second buffer-side internal channel substrate pads 124b, respectively, by substrate wiring.

In example embodiments, the first group of semiconductor chips 300 may be stacked on the first buffer chip 200a and the second buffer chip 200b. The third group of semiconductor chips 500 may be stacked on the first group of semiconductor chips 300, the second group of semiconductor chips 400 may be stacked on the third group of semiconductor chips 500, and the fourth group of semiconductor chips 600 may be stacked on the second group of semiconductor chips 400. First, second, third, and fourth lower semiconductor chips 300a, 300b, 300c, and 300d of the first group of semiconductor chips 300 may be sequentially offset in the second direction (X direction) on the package substrate 110. First, second, third, and fourth lower semiconductor chips 500a, 500b, 500c, and 500d of the third group of semiconductor chips 500 may be sequentially offset in the second direction (X direction) on the uppermost semiconductor chip (the fourth lower semiconductor chip 300d) of the first group of semiconductor chips 300. In some embodiments, the first, second, third, and fourth lower semiconductor chips 500a, 500b, 500c, and 500d of the third group of semiconductor chips 500 may be sequentially offset in a direction opposite to the direction in which the first, second, third, and fourth lower semiconductor chips 300a, 300b, 300c, and 300d of the first group of semiconductor chips 300 are sequentially offset. First, second, third, and fourth upper semiconductor chips 400a, 400b, 400c, and 400d of the second group of semiconductor chips 400 may be sequentially offset in the second direction (X direction) on the uppermost semiconductor chip (e.g., the fourth lower semiconductor chip 500d) of the third group of semiconductor chips 500. In some embodiments, the first, second, third, and fourth upper semiconductor chips 400a, 400b, 400c, and 400d of the second group of semiconductor chips 400 may be sequentially offset in a direction opposite to the direction in which the first, second, third, and fourth lower semiconductor chips 500a, 500b, 500c, and 500d of the third group of semiconductor chips 500 are sequentially offset. First, second, third, and fourth upper semiconductor chips 600a, 600b, 600c, and 600d of the fourth group of semiconductor chips 600 may be sequentially offset in the second direction (X direction) on the uppermost semiconductor chip (e.g., the fourth semiconductor chip 400d) of the second group of semiconductor chips 400. In some embodiments, the first, second, third, and fourth upper semiconductor chips 600a, 600b, 600c, and 600d of the fourth group of semiconductor chips 600 may be sequentially offset in a direction opposite to the direction in which the first, second, third, and fourth upper semiconductor chips 400a, 400b, 400c, and 400d of the second group of semiconductor chips 400 are sequentially offset.

When viewed from plan view, the first upper semiconductor chip 400a of the second group of semiconductor chips 400 may overlap with the first lower semiconductor chip 300a of the first group of semiconductor chips 300, the second upper semiconductor chip 400b may overlap with the second lower semiconductor chip 300b, the third upper semiconductor chip 400c may overlap with the third lower semiconductor chip 300c, and the fourth upper semiconductor chip 400d may overlap with the fourth lower semiconductor chip 300d. For example, side surfaces of the first upper semiconductor chip 400a of the second group of semiconductor chips 400 and the first lower semiconductor chip 300a of the first group of semiconductor chips 300 may align with each other in the third direction (Z direction). Side surfaces of the second upper semiconductor chip 400b of the second group of semiconductor chips 400 and the second lower semiconductor chip 300b of the first group of semiconductor chips 300 may align with each other in the third direction (Z direction). Side surfaces of the third upper semiconductor chip 400c of the second group of semiconductor chips 400 and the third lower semiconductor chip 300c of the first group of semiconductor chips 300 may align with each other in the third direction (Z direction). Side surfaces of the fourth upper semiconductor chip 400d of the second group of semiconductor chips 400 and the fourth lower semiconductor chip 300d of the first group of semiconductor chips 300 may align with each other in the third direction (Z direction).

When viewed from plan view, the first upper semiconductor chip 600a of the fourth group of semiconductor chips 600 may overlap with the first lower semiconductor chip 500a of the third group of semiconductor chips 500, the second upper semiconductor chip 600b may overlap with the second lower semiconductor chip 500b, the third upper semiconductor chip 600c may overlap with the third lower semiconductor chip 500c, and the fourth upper semiconductor chip 600d may overlap with the fourth lower semiconductor chip 500d. For example, side surfaces of the first upper semiconductor chip 600a of the fourth group of semiconductor chips 600 and the first lower semiconductor chip 500a of the third group of semiconductor chips 500 may align with each other in the third direction (Z direction). Side surfaces of the second upper semiconductor chip 600b of the fourth group of semiconductor chips 600 and the second lower semiconductor chip 500b of the third group of semiconductor chips 500 may align with each other in the third direction (Z direction). Side surfaces of the third upper semiconductor chip 600c of the fourth group of semiconductor chips 600 and the third lower semiconductor chip 500c of the third group of semiconductor chips 500 may align with each other in the third direction (Z direction). Side surfaces of the fourth upper semiconductor chip 600d of the fourth group of semiconductor chips 600 and the fourth lower semiconductor chip 500d of the third group of semiconductor chips 500 may align with each other in the third direction (Z direction).

In example embodiments, the first group of semiconductor chips 300 and the second group of semiconductor chips 400 may be (electrically) connected to the package substrate 110 by second bonding wires BW as conductive connection members. The second bonding wires BW may include first channel wires 340 and second channel wires 440. The first channel wires 340 may (electrically) connect chip pads 310 of the first group of semiconductor chips 300 to the first channel memory-side pads 126_A of the package substrate 110. The second channel wires 440 may (electrically) connect chip pads 410 of the second group of semiconductor chips 400 to the second channel memory-side pads 126_B of the package substrate 110.

In example embodiments, the third group of semiconductor chips 500 and the fourth group of semiconductor chips 600 may be (electrically) connected to the package substrate 110 by the second bonding wires BW as conductive connection members. The second bonding wires BW may include third channel wires 540 and fourth channel wires 640. The third channel wires 540 may (electrically) connect chip pads 510 of the third group of semiconductor chips 500 to the third channel memory-side pads 126_C of the package substrate 110. The fourth channel wires 640 may (electrically) connect chip pads 610 of the fourth group of semiconductor chips 600 to the fourth channel memory-side pads 126_D of the package substrate 110.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a package substrate having first substrate pads and second substrate pads on an upper surface of the package substrate, wherein the first substrate pads are spaced apart from each other in a first direction that is parallel with the upper surface of the package substrate, and the second substrate pads are electrically connected to the first substrate pads, respectively, by first substrate wirings that are in the package substrate;
a first buffer chip on the upper surface of the package substrate, wherein the first buffer chip has a first side and a second side that extend in the first direction and that are opposite to each other in a second direction that is parallel with the upper surface of the package substrate, and the first buffer chip includes first buffer chip pads on an upper surface of the first buffer chip;
a first group of semiconductor chips on the upper surface of the package substrate and including at least two first lower semiconductor chips, wherein the at least two first lower semiconductor chips include first lower chip pads on upper surfaces of the at least two first lower semiconductor chips;
a second group of semiconductor chips on the first group of semiconductor chips and including at least two first upper semiconductor chips, wherein the at least two first upper semiconductor chips include first upper chip pads on upper surfaces of the at least two first upper semiconductor chips;
first bonding wires electrically connecting the first buffer chip pads of the first buffer chip to the first substrate pads of the package substrate; and
second bonding wires electrically connecting the first lower chip pads and the first upper chip pads to the second substrate pads of the package substrate,
wherein the first direction and the second direction intersect each other,
wherein the first buffer chip pads include first channel buffer pads and second channel buffer pads that are alternately arranged in the first direction along the first side of the first buffer chip,
wherein the first channel buffer pads are electrically connected to the first lower chip pads by the first bonding wires and the second bonding wires, and
wherein the second channel buffer pads are electrically connected to the first upper chip pads by the first bonding wires and the second bonding wires.

2. The semiconductor package of claim 1, wherein the first channel buffer pads and the second channel buffer pads include data signal pads for transmitting data signals.

3. The semiconductor package of claim 2, wherein the first buffer chip pads further include a ground pad and/or a power pad between the data signal pads in the first direction.

4. The semiconductor package of claim 1, wherein at least one of the first buffer chip pads is spaced apart from the first side of the first buffer chip by a first distance in the second direction, and at least another one of the first buffer chip pads is spaced apart from the first side of the first buffer chip by a second distance greater than the first distance in the second direction.

5. The semiconductor package of claim 1, wherein the first substrate pads and the second substrate pads are arranged between the first side of the first buffer chip and the first group of semiconductor chips in the second direction.

6. The semiconductor package of claim 1, wherein the at least two first lower semiconductor chips and the at least two first upper semiconductor chips are sequentially offset in the second direction, and the second direction is perpendicular to the first direction.

7. The semiconductor package of claim 1, wherein the first group of semiconductor chips on the first buffer chip.

8. The semiconductor package of claim 1, further comprising:
a second buffer chip on the upper surface of the package substrate, wherein the second buffer chip includes second buffer chip pads on an upper surface of the second buffer chip;
third substrate pads on the upper surface of the package substrate;
fourth substrate pads that are electrically connected to the third substrate pads by second substrate wirings that are in the package substrate;
a third group of semiconductor chips on the upper surface of the package substrate and including at least two second lower semiconductor chips, wherein the at least two second lower semiconductor chips include second lower chip pads on upper surfaces of the at least two second lower semiconductor chips; and
a fourth group of semiconductor chips on the third group of semiconductor chips and including at least two second upper semiconductor chips, wherein the at least two second upper semiconductor chips include second upper chip pads on upper surfaces of the at least two second upper semiconductor chips;
third bonding wires electrically connecting the second buffer chip pads of the second buffer chip to the third substrate pads of the package substrate; and
fourth bonding wires electrically connecting the second lower chip pads and the second upper chip pads to the fourth substrate pads of the package substrate.

9. The semiconductor package of claim 8, wherein the second buffer chip is spaced apart from the first buffer chip in the second direction or is on the first buffer chip.

10. The semiconductor package of claim 1, further comprising:
a sealing member on the first buffer chip, the first group of semiconductor chips, and the second group of semiconductor chips on the package substrate.

11. A semiconductor package, comprising:
a package substrate having external channel substrate pads, first substrate pads, and second substrate pads on an upper surface of the package substrate, wherein the first substrate pads and the second substrate pads are electrically connected to each other in one-to-one correspondence;
a first buffer chip on the upper surface of the package substrate, wherein the first buffer chip has a first side and a second side that that are opposite to each other in a first direction, and the first buffer chip includes first buffer chip pads that are arranged in a second direction along the first side and external channel chip pads that are arranged in the second direction along the second side;
a first group of semiconductor chips on the upper surface of the package substrate and including at least two first lower semiconductor chips, wherein the at least two first lower semiconductor chips include first lower chip pads on upper surfaces of the at least two first lower semiconductor chips;
a second group of semiconductor chips on the first group of semiconductor chips and including at least two first upper semiconductor chips, wherein the at least two first upper semiconductor chips include first upper chip pads on upper surfaces of the at least two first upper semiconductor chips;
first bonding wires electrically connecting the first buffer chip pads of the first buffer chip to the first substrate pads of the package substrate;
second bonding wires electrically connecting the external channel chip pads of the first buffer chip to the external channel substrate pads of the package substrate; and
third bonding wires electrically connecting the first lower chip pads and the first upper chip pads to the second substrate pads of the package substrate,
wherein the first direction and the second direction are parallel with the upper surface of the package substrate,
wherein the first direction and the second direction intersect each other,
wherein the first buffer chip pads include first channel buffer pads and second channel buffer pads that are alternately arranged in the second direction along the first side of the first buffer chip,
wherein the first substrate pads include first channel buffer-side pads and second channel buffer-side pads,
wherein the first channel buffer-side pads are electrically connected to the first channel buffer pads in one-to-one correspondence,
wherein the second channel buffer-side pads are electrically connected to the second channel buffer pads in one-to-one correspondence,
wherein the second substrate pads include first channel memory-side pads and second channel memory-side pads,
wherein the first channel memory-side pads are electrically connected to the first channel buffer-side pads in one-to-one correspondence, and
wherein the second channel memory-side pads are electrically connected to the second channel buffer-side pads in one-to-one correspondence.

12. The semiconductor package of claim 11, wherein the third bonding wires include first channel wires that electrically connect the first lower chip pads to the first channel memory-side pads and second channel wires that electrically connect the first upper chip pads to the second channel memory-side pads.

13. The semiconductor package of claim 11, wherein the first channel buffer pads and the second channel buffer pads include data signal pads for transmitting data signals.

14. The semiconductor package of claim 13, wherein the first buffer chip pads further include a ground pad and/or a power pad between the data signal pads in the second direction.

15. The semiconductor package of claim 11, wherein the first channel buffer pads are spaced apart from the first side of the first buffer chip by a first distance in the first direction, and the second channel buffer pads are spaced apart from the first side of the first buffer chip by a second distance greater than the first distance in the first direction.

16. The semiconductor package of claim 11, wherein the first substrate pads and the second substrate pads are arranged between the first side of the first buffer chip and the first group of semiconductor chips in the first direction.

17. The semiconductor package of claim 11, wherein the first group of semiconductor chips are on the first buffer chip.

18. The semiconductor package of claim 11, further comprising:
a second buffer chip on the upper surface of the package substrate, having third side and fourth side that are opposite to each other in the first direction, and having second buffer chip pads arranged in the second direction along the third side of the second buffer chip;
third substrate pads on the upper surface of the package substrate;
fourth substrate pads on the upper surface of the package substrate, wherein the fourth substrate pads are electrically connected to the third substrate pads in one-to-one correspondence;
a third group of semiconductor chips on the upper surface of the package substrate and including at least two second lower semiconductor chips, wherein the at least two second lower semiconductor chips include second lower chip pads on upper surfaces of the at least two second lower semiconductor chips;
a fourth group of semiconductor chips on the third group of semiconductor chips and including at least two second upper semiconductor chips, wherein the at least two second upper semiconductor chips include second upper chip pads on upper surfaces of the at least two second upper semiconductor chips;
fourth bonding wires electrically connecting the second buffer chip pads of the second buffer chip to the third substrate pads of the package substrate; and
fifth bonding wires electrically connecting the second lower chip pads and the second upper chip pads to the fourth substrate pads of the package substrate.

19. The semiconductor package of claim 18, wherein the second buffer chip is spaced apart from the first buffer chip in the first direction or is on the first buffer chip.

20. A semiconductor package, comprising:
a package substrate having first substrate pads and second substrate pads on an upper surface of the package substrate, wherein the first substrate pads and the second substrate pads are electrically connected to each other in one-to-one correspondence;
a buffer chip on the upper surface of the package substrate, wherein the buffer chip has a first side and a second side that are opposite to each other in a first direction, and the buffer chip includes buffer chip pads arranged in a second direction along the first side;
a first group of semiconductor chips including at least two lower semiconductor chips that are sequentially stacked on the upper surface of the package substrate;
a second group of semiconductor chips including at least two upper semiconductor chips that are sequentially stacked on the first group of semiconductor chips;
first bonding wires electrically connecting the buffer chip pads of the buffer chip to the first substrate pads of the package substrate; and
second bonding wires electrically connecting lower chip pads of the first group of semiconductor chips and upper chip pads of the second group of semiconductor chips to the second substrate pads of the package substrate,
wherein the buffer chip pads include first channel buffer pads and second channel buffer pads that are alternately arranged in the second direction along the first side,
wherein the first direction and the second direction are parallel with the upper surface of the package substrate,
wherein the first direction and the second direction intersect each other,
wherein the first substrate pads include first channel buffer-side pads and second channel buffer-side pads,
wherein the first channel buffer-side pads are electrically connected to the first channel buffer pads in one-to-one correspondence,
wherein the second channel buffer-side pads are electrically connected to the second channel buffer pads in one-to-one correspondence,
wherein the second substrate pads include first channel memory-side pads and second channel memory-side pads,
wherein the first channel memory-side pads are electrically connected to the first channel buffer-side pads in one-to-one correspondence,
wherein the second channel memory-side pads are electrically connected to the second channel buffer-side pads in one-to-one correspondence,
wherein the first channel buffer pads, the first channel buffer-side pads, and the first channel memory-side pads constitute at least a portion of a first channel for transmitting data signals between the buffer chip and the first group of semiconductor chips, and
wherein the second channel buffer pads, the second channel buffer-side pads, and the second channel memory-side pads constitute at least a portion of a second channel for transmitting data signals between the buffer chip and the first group of semiconductor chips.
